(19) United States
(12) Patent Application Publication
(10) Pub. No.: US 2025/0255119 A1
(43) Pub. Date: Aug. 7, 2025

(54) DISPLAY DEVICE

(71) Applicant: LG DISPLAY CO., LTD., Seoul (KR)

(72) Inventor: MyungHo BAN, Paju-si (KR)

(73) Assignee: LG DISPLAY CO., LTD., Seoul (KR)

(21) Appl. No.: 19/001,103

(22) Filed: Dec. 24, 2024

(30) Foreign Application Priority Data
Feb. 2, 2024 (KR) 10-2024-0016853

(51) Int. Cl. H10K 59/124; H10K 59/121; H10K 59/122; H10K 59/131; H10K 59/80

(52) U.S. Cl. CPC H10K 59/124; H10K 59/121; H10K 59/131; H10K 59/80521; H10K 59/122

(57) ABSTRACT

A display device according to embodiments of the present disclosure may include a substrate, a first protective layer located on the substrate, a first insulating layer located on the first protective layer, a second insulating layer located on the first protective layer and disposed on one side of the first insulating layer, N first pixel electrodes located on the first insulating layer, K second pixel electrodes located on the first protective layer and disposed between one side of the first insulating layer and the other side of the second insulating layer, and M third pixel electrodes located on the second insulating layer.

### CROSS REFERENCE TO RELATED APPLICATION

This application claims priority from Korean Patent Application No. 10-2024-0016853, filed on Feb. 2, 2024, which is hereby incorporated by reference for all purposes as if fully set forth herein.

### BACKGROUND

### Technical Field

Embodiments of the present disclosure relate to a display device.

### Discussion of the Related Art

Among display devices, there is a self-luminous display device in which a display panel emits light on its own. In the case of a self-luminous display device, the display panel may include a light emitting device for each subpixel.

Meanwhile, the light generated from the light emitting devices of the display panel may pass through various components within the display panel, and come out of the display panel. However, among the light generated from the light emitting device, there may be light that does not come out of the display panel and is trapped inside the display panel.

Among the light generated from the light emitting device, the more light that does not come out of the display panel and is trapped inside the display panel, the lower the luminance of the corresponding subpixel may be. Accordingly, as a result, there may be deteriorated the quality of the image displayed on the display panel.

### SUMMARY

Accordingly, embodiments of the present disclosure are directed to a display device that substantially obviates one or more of the problems due to limitations and disadvantages of the related art.

An aspect of the present disclosure is to provide a display device having a light extraction structure which allows a greater amount of light among the light generated by the light emitting devices in the display panel to be emitted toward a viewing surface.

Another aspect of the present disclosure is to provide a display device having a light extraction structure suitable for a high-resolution display panel.

Another aspect of the present disclosure is to provide a display device with a compensation function capable of reducing luminance deviation for each subpixel according to a light extraction structure suitable for high-resolution display panels.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display device may comprise a substrate, a first protective layer located on the substrate, a first insulating layer located on the first protective layer, a second insulating layer located on the first protective layer and disposed on one side of the first insulating layer, N first pixel electrodes located on the first insulating layer, K second pixel electrodes located on the first protective layer and disposed between one side of the first insulating layer and one side of the second insulating layer which is adjacent to the one side of the first insulating layer, and M third pixel electrodes located on the second insulating layer. Here, N may be a natural number greater than or equal to 2, K may be a natural number greater than or equal to 1, and M may be a natural number greater than or equal to 2.

In another aspect, a display device may comprise a substrate, a first pixel electrode, a second pixel electrode, and a third pixel electrode on the substrate, an intermediate layer on the first pixel electrode, the second pixel electrode, and the third pixel electrode, and a common electrode on the intermediate layer, wherein the first pixel electrode and the third pixel electrode are located higher from the substrate than the second pixel electrode.

In a display device according to embodiments of the present disclosure, the common electrode may include an inclined surface extending from an upper portion of the first pixel electrode, passing through one side of the first pixel electrode, and extending to an upper portion of the second pixel electrode, and an inclined surface extending from an upper portion the third pixel electrode, passing through the other side of the third pixel electrode, and extending to an upper portion of the second pixel electrode.

A display device according to embodiments of the present disclosure may further comprise an insulating layer which is not disposed below the second pixel electrode, but is disposed below the first pixel electrode and the third pixel electrode.

In another aspect, a display device may comprise a substrate, a first protective layer on the substrate, a first insulating layer located on the first protective layer, a second insulating layer located on the first protective layer and laterally spaced apart from the first insulating layer, a first light emitting device located on the first insulating layer and included in a first subpixel, a second light emitting device located on the first protective layer, disposed in a lateral direction of the first insulating layer and the second insulating layer, and included in a second subpixel, and a third light emitting device located on the second insulating layer and included in the third subpixel. In this case, the second light emitting device may be located closer to the substrate than the first light emitting device and the third light emitting device.

In a display device according to embodiments of the present disclosure, if an emission luminance of the first subpixel, an emission luminance of the second subpixel, and an emission luminance of the third subpixel are the same, a data voltage supplied to the second subpixel may be higher than a data voltage supplied to each of the first subpixel and the third subpixel.

A display device according to embodiments of the present disclosure may further comprise a first pixel electrode located on the first insulating layer and included in the first light emitting device, a second pixel electrode located on the first protective layer, disposed between one side of the first insulating layer and one side of the second insulating layer which is adjacent to the one side of the first insulating layer, and included in the second light emitting device, and a third pixel electrode located on the second insulating layer and included in the third light emitting device.

A display device according to embodiments of the present disclosure may further comprise an intermediate layer on the first pixel electrode, the second pixel electrode, and the third pixel electrode, and a common electrode on the intermediate layer.

In a display device according to embodiments of the present disclosure, the second pixel electrode may be located closer to the substrate than the first pixel electrode and the third pixel electrode.

In a display device according to embodiments of the present disclosure, the common electrode may include an inclined surface extending from an upper portion of the first pixel electrode, passing through one side of the first pixel electrode, and extending to an upper portion of the second pixel electrode, and an inclined surface extending from an upper portion of the third pixel electrode, passing through one side of the third pixel electrode, which is adjacent to the one side of the first pixel electrode and extending to an upper portion of the second pixel electrode.

According to embodiments of the present disclosure, there may provide a display device having a light extraction structure which allows a greater amount of light among the light generated by the light emitting devices in the display panel to be emitted toward a viewing surface.

According to embodiments of the present disclosure, there may provide a display device having a light extraction structure suitable for a high-resolution display panel.

According to embodiments of the present disclosure, there may provide a display device with a compensation function capable of reducing luminance deviation for each subpixel according to a light extraction structure suitable for high-resolution display panels.

According to embodiments of the present disclosure, it is possible to increase the light extraction efficiency for light generated from light emitting devices in the display panel. Accordingly, it is possible to reduce the power consumption of the display device by increasing light extraction efficiency.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles.

FIG. 1 is a system configuration diagram of a display device according to embodiments of the present disclosure.

FIG. 2 illustrates a display panel according to embodiments of the present disclosure.

FIG. 3 illustrates subpixels of a display panel according to embodiments of the present disclosure.

FIG. 4 is a plan view of a display panel according to embodiments of the present disclosure.

FIG. 5 illustrates an area of a subpixel of a display panel according to embodiments of the present disclosure.

FIGS. 6 and 7 illustrate a light extraction structure of a display panel according to embodiments of the present disclosure.

FIG. 8 is a plan view illustrating a light extraction structure of a display panel according to embodiments of the present disclosure.

FIGS. 9 and 10 are cross-sectional views illustrating a light extraction structure of a display panel according to embodiments of the present disclosure.

FIG. 11 illustrates the number of mirrors per subpixel of the display panel according to embodiments of the present disclosure.

FIG. 12 illustrates light extraction efficiency for each subpixel of a display panel according to embodiments of the present disclosure.

FIG. 13 illustrates the light emission state for each subpixel of the display panel according to embodiments of the present disclosure.

FIG. 14 illustrates a data compensation circuit considering the light extraction structure of a display device according to embodiments of the present disclosure.

FIG. 15 illustrates data compensation values for each subpixel considering a light extraction structure of the display panel according to embodiments of the present disclosure.

FIG. 16 illustrates the light emission state of each subpixel after data compensation considering a light extraction structure of the display panel according to embodiments of the present disclosure.

### DETAILED DESCRIPTION

Hereinafter, embodiments of the disclosure are described in detail with reference to the accompanying drawings. In assigning reference numerals to components of each drawing, the same components may be assigned the same numerals even when they are shown on different drawings. When determined to make the subject matter of the disclosure unclear, the detailed of the known art or functions may be skipped. As used herein, when a component “includes,” “has,” or “is composed of” another component, the component may add other components unless the component “only” includes, has, or is composed of” the other component. As used herein, the singular forms “a”, “an” and “the” are intended to include the plural forms as well, unless the context clearly indicates otherwise.

Such denotations as “first,” “second,” “A,” “B,” “(a),” and “(b),” may be used in describing the components of the disclosure. These denotations are provided merely to distinguish a component from another, and the essence, order, or number of the components are not limited by the denotations.

In describing the positional relationship between components, when two or more components are described as “connected”, “coupled” or “linked”, the two or more components may be directly “connected”, “coupled” or “linked”, or another component may intervene. Here, the other component may be included in one or more of the two or more components that are “connected”, “coupled” or “linked” to each other.

When such terms as, e.g., “after”, “next to”, “after”, and “before”, are used to describe the temporal flow relationship related to components, operation methods, and fabricating methods, it may include a non-continuous relationship unless the term “immediately” or “directly” is used.

When a component is designated with a value or its corresponding information (e.g., level), the value or the corresponding information may be interpreted as including a tolerance that may arise due to various factors (e.g., process factors, internal or external impacts, or noise).

Hereinafter, various embodiments of the disclosure are described in detail with reference to the accompanying drawings.

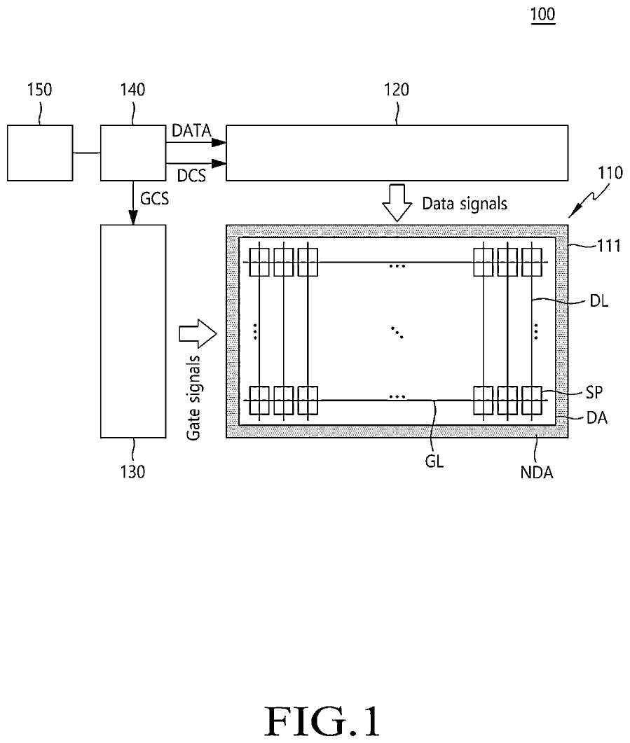

FIG. 1 is a system configuration diagram of a display device 100 according to embodiments of the present disclosure.

Referring to FIG. 1, a display device 100 according to embodiments of the present disclosure may include a display panel 110 and a display driving circuit as components for displaying an image. The display driving circuit is a circuit for driving the display panel 110, and may include a data driving circuit 120, a gate driving circuit 130, and a controller 140.

The display panel 110 may include a substrate 111 and a plurality of subpixels SP disposed on the substrate 111.

The substrate 111 of the display panel 110 may include a display area DA capable of displaying an image and a non-display area NDA located outside the display area DA.

The display area DA may also be referred to as an active area, and a plurality of subpixels SP for image display may be disposed in the display area DA. The non-display area NDA may also be referred to as a non-active area and may include a pad area.

In a display panel 110 according to embodiments of the present disclosure, the non-display area NDA may be very small. In this specification, the non-display area NDA may be also referred to as a “bezel.” For example, the non-display area NDA may include a first non-display area located outside the display area DA in a first direction, a second non-display area located outside the display area DA in a second direction different from the first direction, a third non-display area located outside the display area DA in the opposite direction to the first direction, and a fourth non-display area located outside the display area DA in the direction opposite to the second direction.

The first non-display area may include a pad area to which the driving circuit is connected or bonded. The second to fourth non-display areas may have a very small size.

For another example, a boundary area between the display area DA and the non-display area NDA may be bent so that the non-display area NDA may be located below the display area. In this case, when the user looks at the display device 100 from the front, there may be little or no non-display area NDA visible to the user. For example, the first non-display area may include a bending area. As the bending area is bent, the first non-display area may not be visible from the front.

Various types of signal lines for driving a plurality of subpixels SP may be disposed on the substrate 111 of the display panel 110.

The display device 100 according to embodiments of the present disclosure may be a self-luminous display device in which the display panel 110 emits light on its own. if the display device 100 according to embodiments of the present disclosure is a self-luminous display device, each of the plurality of subpixels SP may include a light emitting device.

For example, the display device 100 according to embodiments of the present disclosure may be an organic light emitting display device in which a light emitting device is implemented as an organic light emitting diode (OLED). For another example, the display device 100 according to embodiments of the present disclosure may be an inorganic light emitting display device in which the light emitting device is implemented as an inorganic-based light emitting diode. For another example, the display device 100 according to embodiments of the present disclosure may be a quantum dot display device in which a light emitting device is implemented with quantum dots, which are semiconductor crystals emitting light by itself.

The structure of each of the plurality of subpixels SP may vary depending on the type of the display device 100. For example, if the display device 100 is a self-luminous display device with the subpixel SP emitting light by itself, each subpixel SP may include a self-luminous light emitting device, one or more transistors, and one or more capacitors.

For example, various types of signal lines may include a plurality of data lines DL supplying data signals (also called data voltages or image signals) and a plurality of gate lines GL for transmitting gate signals (also called scan signals).

For example, the plurality of data lines DL and the plurality of gate lines GL may cross each other. Each of the plurality of data lines DL may be arranged to extend in a first direction. Each of the plurality of gate lines GL may be arranged to extend in a second direction. Here, the first direction may be a column direction and the second direction may be a row direction. Alternatively, the first direction may be a row direction and the second direction may be a column direction. Hereinafter, for convenience of explanation, it will exemplified a case in which each of the plurality of data lines DL is arranged in a column direction, and each of the plurality of gate lines GL is arranged in a row direction, however is not limited thereto.

The data driving circuit 120 is a circuit for driving a plurality of data lines DL, and may output data signals to the plurality of data lines DL.

The data driving circuit 120 may receive image data in digital form from the display controller 140 and convert the received image data into analog data signals to output to a plurality of data lines DL.

For example, the data driving circuit 120 may be connected to the display panel 110 using a tape automated bonding (TAB) method, or may be connected to the bonding pad of the display panel 110 using a chip-on-glass (COG) or chip-on-panel (COP) method, or may be implemented using a chip-on-film (COF) method and connected to the display panel 110, however is not limited thereto.

The data driving circuit 120 may be connected to one side (e.g., the upper or lower side) of the display panel 110. Depending on the driving method, panel design method, etc., the data driving circuit 120 may be connected to both sides (e.g., upper and lower sides) of the display panel 110, or may be connected to two or more of the four sides of the display panel 110.

The data driving circuit 120 may be connected to the outside of the display area DA of the display panel 110, but alternatively, it may be disposed in the display area DA of the display panel 110.

The gate driving circuit 130 is a circuit for driving a plurality of gate lines GL, and may output gate signals to the plurality of gate lines GL.

The gate driving circuit 130 may receive a first gate voltage corresponding to the turn-on level voltage and a second gate voltage corresponding to the turn-off level voltage along with various gate driving control signals GCS, and may generate gate signals and supply the generated gate signals to the plurality of gate lines GL.

In the display device 100 according to embodiments of the present disclosure, the gate driving circuit 130 may be built into the display panel 110 as a gate-in-panel (GIP) type. If the gate driving circuit 130 is a gate-in-panel type, the gate driving circuit 130 may be formed on a substrate of the display panel 110 during the manufacturing process of the display panel 110.

For example, in the display device 100 according to embodiments of the present disclosure, the gate driving circuit 130 may be disposed in the non-display area NDA of the display panel 110.

As another example, the gate driving circuit 130 may be disposed in the display area DA of the display panel 110. In this case, the gate driving circuit 130 may be disposed in a first partial area within the display area DA (e.g., a left area or a right area within the display area DA). For another example, the gate driving circuit 130 may be disposed in a first partial area within the display area DA (e.g., a left area or a right area within the display area DA) and a second partial area (e.g., a right area or a left area within the display area DA).

In the present disclosure, a gate driving circuit 130 built into the display panel 110 as a gate-in-panel type may be referred to as a “gate-in-panel circuit.”

The controller 140 may be a device for controlling the data driving circuit 120 and the gate driving circuit 130, and may control the driving timing for the plurality of data lines DL and the driving timing of the plurality of gate lines GL.

The controller 140 may supply a data driving control signal DCS to the data driving circuit 120 to control the data driving circuit 120, and may supply a gate driving control signal GCS to the gate driving circuit 130 to control the gate driving circuit 130.

The controller 140 may receive input image data from a host system 150 and supply image data DATA to the data driving circuit 120 based on the input image data.

The controller 140 may be implemented as a separate component from the data driving circuit 120, or may be integrated with the data driving circuit 120 and implemented as an integrated circuit.

The controller 140 may be a timing controller used in typical display technology, or may be a control device capable of further performing other control functions including a timing controller, or may be a control device different from the timing controller, or may be a control device other than a timing controller, or may be a circuit within the control device. The controller 140 may be implemented with various circuits or electronic components, such as an integrated circuit (IC), a field programmable gate array (FPGA), an application specific integrated circuit (ASIC), or Processor.

The controller 140 may be mounted on a printed circuit board, a flexible printed circuit, etc., and may be electrically connected to the data driving circuit 120 and the gate driving circuit 130 through a printed circuit board, a flexible printed circuit.

The controller 140 may transmit and receive signals with the data driving circuit 120 according to one or more predetermined interfaces. For example, the interface may include a low voltage differential signaling (LVDS) interface, an embedded clock point-point interface (EPI), or a serial peripheral interface (SPI), however is not limited thereto.

In order to provide not only an image display function but also a touch sensing function, the display device 100 according to embodiments of the present disclosure may include a touch sensor and a touch sensing circuit for detecting an occurrence of a touch by a touch object such as a finger or pen or detection a touch position by sensing the touch sensor.

The touch sensing circuit may include a touch driving circuit for driving and sensing a touch sensor to generate and output touch sensing data, and a touch controller for detecting the occurrence of a touch or detecting the touch position using touch sensing data.

A touch sensor may include a plurality of touch electrodes. The touch sensor may further include a plurality of touch lines to electrically connect a plurality of touch electrodes and the touch driving circuit.

The touch sensor may exist outside the display panel 110 in the form of a touch panel or may exist inside the display panel 110. If the touch sensor exists outside the display panel 110 in the form of a touch panel, the touch sensor may be referred to as an external type. If the touch sensor is an external type, the touch panel and the display panel 110 may be manufactured separately and combined during the assembly process. The external touch panel may include a touch panel substrate and a plurality of touch electrodes on the touch panel substrate.

If the touch sensor exists inside the display panel 110, the touch sensor may be formed on the substrate along with signal lines and electrodes related to display driving during the manufacturing process of the display panel 110.

The touch driving circuit may supply a touch driving signal to at least one of the plurality of touch electrodes and generate touch sensing data by sensing at least one of the plurality of touch electrodes.

The touch sensing circuit may perform touch sensing using a self-capacitance sensing method or a mutual-capacitance sensing method.

If the touch sensing circuit performs touch sensing using a self-capacitance sensing method, the touch sensing circuit may perform touch sensing based on the capacitance between each touch electrode and a touch object (e.g., finger, pen, etc.). According to the self-capacitance sensing method, each of the plurality of touch electrodes may serve as a driving touch electrode and a sensing touch electrode. The touch driving circuit may drive all or part of the plurality of touch electrodes and sense all or part of the plurality of touch electrodes.

If the touch sensing circuit performs touch sensing using the mutual-capacitance sensing method, the touch sensing circuit may perform touch sensing based on the capacitance between touch electrodes. According to the mutual-capacitance sensing method, the plurality of touch electrodes may be divided into driving touch electrodes and sensing touch electrodes. The touch driving circuit may drive driving touch electrodes and sense sensing touch electrodes.

The touch driving circuit and the touch controller included in the touch sensing circuit may be implemented as separate devices or as one device. Additionally, the touch driving circuit and the data driving circuit may be implemented as separate devices or as one device.

The display device 100 may further include a power supply circuit which supplies various types of power to the display driving circuit and/or the touch sensing circuit.

The display device 100 according to embodiments of the present disclosure may be a mobile terminal such as a smart phone or tablet, or a monitor or television of various sizes, but is not limited thereto, and may be a display of various types and sizes capable of displaying information or images.

The display device 100 according to embodiments of the present disclosure may further include an electronic device such as a camera (e.g., image sensor) and a detection sensor. For example, the detection sensor may be a sensor for detecting an object or a human body by receiving light such as infrared, ultrasonic, or ultraviolet rays.

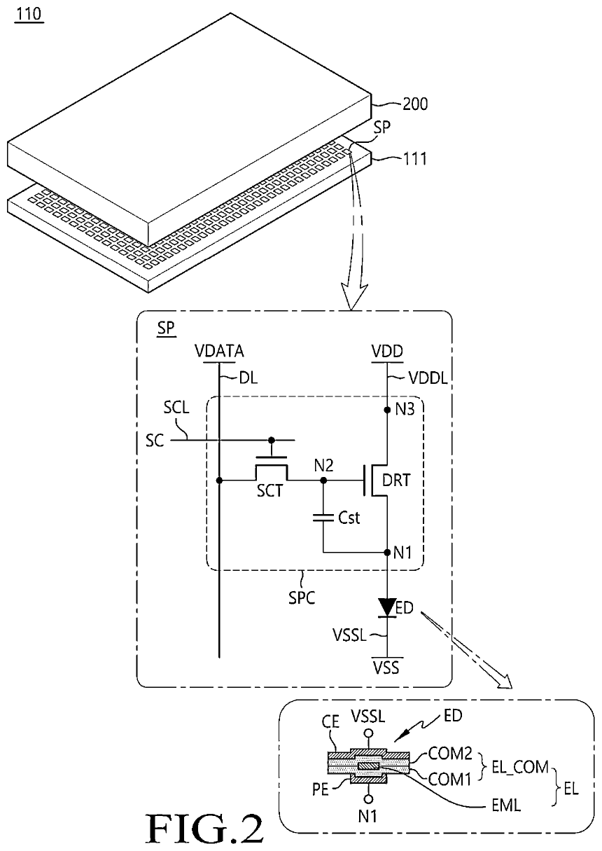

FIG. 2 illustrates a display panel 110 according to embodiments of the present disclosure.

Referring to FIG. 2, the display panel 110 may include a substrate 111 disposed in a plurality of subpixels SP and an encapsulation layer 200 on the substrate 111. Here, the encapsulation layer 200 may also be referred to as an encapsulation substrate or an encapsulation portion.

Referring to FIG. 2, when the display device 100 according to embodiments of the present disclosure is a self-luminous display device, each of the plurality of subpixels SP may include a light emitting device ED and a subpixel circuit SPC for driving the light emitting device ED.

Referring to FIG. 2, the subpixel circuit SPC may include a plurality of pixel driving transistors and at least one capacitor for driving the light emitting device ED. In the present disclosure, the subpixel circuit SPC may drive the light emitting device ED by supplying a driving current to the light emitting device ED at a predetermined timing. The light emitting device ED may be driven by a driving current and emit light.

The plurality of pixel driving transistors may include a driving transistor DRT for driving the light emitting device ED, and a scan transistor SCT which is turned on or off depending on the scan signal SC.

The driving transistor DRT may supply driving current to the light emitting device ED.

The scan transistor SCT may be configured to control the electrical state of a corresponding node (e.g., second node N2) in the subpixel circuit SPC or to control the state or operation of the driving transistor DRT.

At least one capacitor may include a storage capacitor Cst to maintain a constant voltage during the frame.

In order to drive the subpixel SP, a data signal VDATA which is an image signal, and a scan signal SC which is a gate signal may be applied to the subpixel SP. In addition, a common pixel driving voltage including a first common driving voltage VDD and a second common driving voltage VSS may be applied to the subpixel SP in order to drive the subpixel SP.

The light emitting device ED may include a pixel electrode PE, an intermediate layer EL, and a common electrode CE. The intermediate layer EL may be located between the pixel electrode PE and the common electrode CE.

For example, the pixel electrode PE may be an anode AND, and the common electrode CE may be a cathode CAT. Alternatively, the pixel electrode PE may be a cathode CAT and the common electrode CE may be an anode AND. Hereinafter, for convenience of explanation, it is exemplified a case where the pixel electrode PE is an anode AND and the common electrode CE is a cathode CAT.

In the case that the light emitting device ED is an organic light emitting diode, the intermediate layer EL may include an emission layer EML, a first common intermediate layer COM1 between the anode AND and the emission layer EML, and a second common intermediate layer COM2 between the emission layer EML and the cathode CAT. The first common intermediate layer COM1 and the second common intermediate layer COM2 may be collectively referred to as the common intermediate layer EL_COM.

The emission layer EML may be disposed in each subpixel SP. In comparison, the common intermediate layer EL_COM may be commonly disposed across a plurality of subpixels SP.

The emission layer EML may be disposed in each emission area, and the common intermediate layer EL_COM may be commonly disposed across a plurality of emission areas and non-emission areas.

For example, the first common intermediate layer COM1 may include a hole injection layer HIL and a hole transport layer HTL. The second common intermediate layer COM2 may include an electron transport layer ETL and an electron injection layer EIL.

The hole injection layer may inject holes from the pixel electrode PE to the hole transport layer, the hole transport layer may transport holes to the emission layer EML, the electron injection layer may inject electrons from the common electrode CE to the electron transport layer, and the electron transport layer may transport electrons to the emission layer EML.

For example, the common electrode CE may be electrically connected to a second common driving voltage line VSSL. A second common driving voltage VSS, which is a type of common pixel driving voltage, may be applied to the common electrode CE through the second common driving voltage line VSSL. The pixel electrode PE may be electrically connected directly or indirectly (via another transistor) to the first node N1 of the driving transistor DRT of each subpixel SP. In the present disclosure, the second common driving voltage VSS may also be referred to as a base voltage VSS, and the second common driving voltage line VSSL may also be referred to as a base voltage line VSSL.

Each light emitting device ED may be composed of overlapping parts of the pixel electrode PE, the intermediate layer EL and the common electrode CE. A predetermined emission area may be formed by each light emitting device ED. For example, the emission area of each light emitting device ED may include an area where the pixel electrode PE, the intermediate layer EL and the common electrode CE overlap.

For example, the light emitting device ED may be an organic light emitting diode (OLED), an inorganic light emitting diode, or a quantum dot light emitting device. For example, in the case that the light emitting device ED is an organic light emitting diode OLED, the intermediate layer EL in the light emitting device ED may include an organic intermediate layer EL containing an organic material.

The driving transistor DRT may be a driving transistor for supplying driving current to the light emitting device ED. The driving transistor DRT may be connected between a first common driving voltage line VDDL and the light emitting device ED.

The driving transistor DRT may include a first node N1, a second node N2, and a third node N3. The first node N1 may be electrically connected to the light emitting device ED. The data signal VDATA may be applied to the second node N2. The first common driving voltage VDD may be applied to the third node N3 from the first common driving voltage line VDDL.

In the driving transistor DRT, the second node N2 may be a gate node, the first node N1 may be a source node or a drain node, and the third node N3 may be a drain node or a source node. Hereinafter, for convenience of explanation, it will be described a case in which the second node N2 is a gate node (or gate electrode), the first node N1 is a source node (or source electrode, and the third node N3 is a drain node (or drain electrode) in the driving transistor DRT, however embodiments of the present disclosure are not limited thereto.

The scan transistor SCT included in the subpixel circuit SPC illustrated in FIG. 2 may be a switching transistor for transmitting a data signal VDATA, which is an image signal, to the second node N2 which is the gate node of the driving transistor DRT.

The scan transistor SCT may be controlled on-off by the scan signal SC which is a gate signal applied through the scan line SCL as a type of gate line GL, and may control the electrical connection between the second node N2 of the driving transistor DRT and the data line DL. The drain electrode or source electrode of the scan transistor SCT may be electrically connected to the data line DL, and the source electrode or drain electrode of the scan transistor SCT may be electrically connected to the second node N2 of the driving transistor DRT. The gate electrode of the scan transistor SCT may be electrically connected to the scan line SCL.

The storage capacitor Cst may be electrically connected between the first node N1 and the second node N2 of the driving transistor DRT. The storage capacitor Cst may include a first capacitor electrode electrically connected to the first node N1 of the driving transistor DRT or corresponding to the first node N1 of the driving transistor DRT, and a second capacitor electrode electrically connected to the second node N2 of the driving transistor DRT or corresponding to the second node N2 of the driving transistor DRT.

The storage capacitor Cst may be an external capacitor intentionally designed outside the driving transistor DT rather than a parasitic capacitor (e.g., Cgs, Cgd) as an internal capacitor which may exist between the first node N1 and the second node N2 of the driving transistor DRT.

Each of the driving transistor DRT and the scan transistor SCT may be an n-type transistor or a p-type transistor.

The display panel 110 may have a top emission structure that emits light in the front direction, or a bottom emission structure that emits light in the rear direction. Here, the front direction may correspond to the direction from the substrate 111 toward the encapsulation layer 200, and the rear direction may correspond to the direction from the encapsulation layer 200 toward the substrate 111.

If the display panel 110 has a top emission structure, at least a portion of the subpixel circuit SPC may overlap with at least a portion of the light emitting device ED in the vertical direction. Accordingly, the area of the emission area may be increased and the aperture ratio may be increased.

If the display panel 110 has a bottom emission structure, the subpixel circuit SPC may not overlap with the light emitting device ED in the vertical direction.

If the display panel 110 has a top emission structure, the pixel electrode PE may be a reflective electrode and the common electrode CE may be a transparent electrode. If the display panel 110 has a bottom emitting structure, the pixel electrode PE may be a transparent electrode and the common electrode CE may be a reflective electrode.

As shown in FIG. 2, the subpixel circuit SPC may have 2T-1C structure including two transistors T1 and T2 and one capacitor Cst. In some case, the subpixel circuit SPC may further include one or more transistors or one or more capacitors.

For example, the subpixel circuit SPC may have a 8T-1C structure including eight transistors and a single capacitor. For another example, the subpixel circuit SPC may have a 6T-2C structure including six transistors and two capacitors. For another example, the subpixel circuit SPC may have a 7T-1C structure including seven transistors and one capacitor. These are only examples of subpixel circuits SPC, and are not limited thereto.

Depending on the structure of the subpixel circuit SPC, there may vary the type and number of gate signal and/or gate lines supplied to the subpixel SP. In addition, depending on the structure of the subpixel circuit SPC, there may vary the type and number of common driving voltages supplied to the subpixel SP.

Since circuit elements within each subpixel SP (in particular, light emitting devices EDs implemented with organic light emitting diodes (OLEDs) containing organic materials) are vulnerable to external moisture or oxygen, an encapsulation layer 200 may be disposed on the display panel 110 to prevent oxygen from penetrating into the circuit elements (particularly, the light emitting device ED).

The encapsulation layer 200 may be configured in various shapes to prevent the light emitting device ED from coming into contact with moisture or oxygen. For example, the encapsulation layer 200 may be composed of two or more layers in which organic layers and inorganic layers are alternately stacked, but embodiments of the present disclosure are not limited thereto.

Referring to FIG. 2, in order to sense a touch of an user, the display device 100 according to embodiments of the present disclosure may include a touch sensor layer including a plurality of sensor electrodes, a touch driving circuit configured to sense a plurality of sensor electrodes, and a touch controller configured to determine the presence or absence of a touch or touch coordinates using the sensing results (e.g., touch sensing data) of the touch driving circuit.

The touch sensor layer may be built or embedded into the display panel 110.

The display panel 110 may further include a plurality of touch pads to which the touch sensing circuit is electrically connected, and a plurality of touch lines for electrically connecting a plurality of sensor electrodes included in the touch sensor layer and a plurality of touch pads to which the touch sensing circuit is connected.

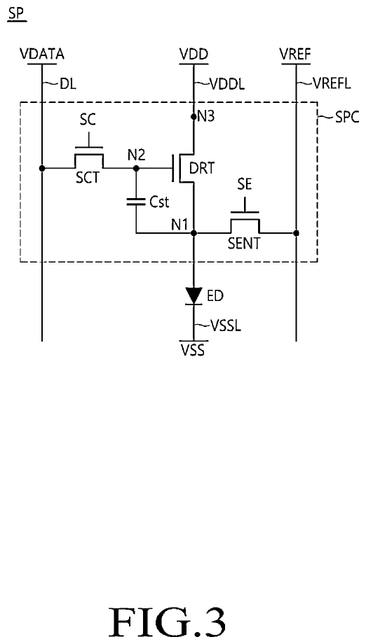

FIG. 3 illustrates a subpixel SP of a display panel 110 according to embodiments of the present disclosure.

Referring to FIG. 3, each of the plurality of subpixels SP disposed on the display panel 110 according to embodiments of the present disclosure may include a light emitting device ED and a subpixel circuit SPC for driving the light emitting device ED.

The subpixel circuit SPC of each subpixel SP illustrated in FIG. 3 may further include a sensing transistor SENT compared to a subpixel SP shown in FIG. 2. That is, the subpixel circuit SPC of each subpixel SP illustrated in FIG. 3 may include a driving transistor DRT, a scan transistor SCT, a sensing transistor SENT, and a storage capacitor Cst.

Referring to FIG. 3, the light emitting device ED may include a pixel electrode PE, a common electrode CE, and an intermediate layer EL located between the pixel electrode PE and the common electrode CE. A first common driving voltage line VSSL may be electrically connected to the common electrode CE.

Referring to FIG. 3, the driving transistor DRT is a transistor for driving the light emitting device ED, and may include a first node N1, a second node N2, and a third node N3.

The first node N1 of the driving transistor DRT may be a source node or a drain node of the driving transistor DRT, may be electrically connected to the source node or drain node of the sensing transistor SENT, and may also be electrically connected to the pixel electrode PE of light emitting device ED.

The second node N2 of the driving transistor DRT may be a gate node of the driving transistor DRT, and may be electrically connected to the source node or drain node of the scan transistor SCT.

The third node N3 of the driving transistor DRT may be electrically connected to the first common driving voltage line VDDL which supplies the first common driving voltage VDD.

Referring to FIG. 3, the scan transistor SCT may be controlled by a scan signal SC, which is a type of gate signal, and may be connected between the second node N2 of the driving transistor DRT and the data line DL. That is, the scan transistor SCT may be turned on or turned off according to the scan signal SC supplied from the scan signal line, which is a type of gate line GL, and may control the connection between the data line DL and the second node N2 of the driving transistor DRT.

The scan transistor SCT may be turned on by the scan signal SC having a turn-on level voltage, and may apply the data voltage VDATA supplied from the data line DL to the second node N2 of the driving transistor DRT.

Here, if the scan transistor SCT is an n-type transistor, the turn-on level voltage of the scan signal SC may be a high-level voltage. If the scan transistor SCT is a p-type transistor, the turn-on level voltage of the scan signal SC may be a low-level voltage. Hereinafter, the scan transistor SCT is exemplified as an n-type transistor. Accordingly, the turn-on level voltage is exemplified as a high-level voltage.

Referring to FIG. 3, the sensing transistor SENT may be controlled by a sensing signal SE, which is a type of gate signal, and may be connected between the first node N1 of the driving transistor DRT and a reference voltage line VREFL. That is, the sensing transistor SENT may be turned on or turned off according to the sensing signal SE supplied from the sensing signal line, which is another type of gate line GL, and may control the connection between the reference voltage line VREFL and the first node N1 of the driving transistor DRT.

The sensing transistor SENT may be turned on by the sensing signal SE having a turn-on level voltage, and may transfer the reference voltage Vref supplied from the reference voltage line VREFL to the first node N1 of the driving transistor DRT. Here, the sensing signal SE may be considered as a second scan signal different from the scan signal SC.

In addition, the sensing transistor SENT may be turned on by the sensing signal SE having a turn-on level voltage, and may transfer the voltage of the first node N1 of the driving transistor DRT to the reference voltage line VREFL.

Here, when the sensing transistor SENT is an n-type transistor, the turn-on level voltage of the sensing signal SE may be a high-level voltage. When the sensing transistor SENT is a p-type transistor, the turn-on level voltage of the sensing signal SE may be a low-level voltage. Hereinafter, for example, there is exemplified the sensing transistor SENT is an n-type transistor, and accordingly, the turn-on level voltage is a high-level voltage.

The function of the sensing transistor SENT to transfer the voltage of the first node N1 of the driving transistor DRT to the reference voltage line VREFL may be used when driving to sense the characteristic value of the subpixel SP. In this case, the voltage transferred to the reference voltage line VREFL may be a voltage for calculating the characteristic value of the subpixel SP or a voltage reflecting the characteristic value of the subpixel SP.

In the present disclosure, the characteristic value of the subpixel SP may be the characteristic value of the driving transistor DRT or the light emitting device ED. For example, the characteristic values of the driving transistor DRT may include a threshold voltage and a mobility of the driving transistor DRT. The characteristic value of the light emitting device ED may include a threshold voltage of the light emitting device ED.

Referring to FIG. 3, the storage capacitor Cst may be connected between the second node N2 and the first node N1 of the driving transistor DRT. The storage capacitor Cst may be charged with a charge corresponding to the voltage difference between the two ends, and may play the role of maintaining the voltage difference between the two ends for a set frame time. Accordingly, the corresponding subpixel SP may emit light during a set frame time.

Referring to FIG. 3, for example, the gate node of the scan transistor SCT and the gate node of the sensing transistor SENT may not be connected. That is, the gate node of the scan transistor SCT and the gate node of the sensing transistor SENT may be connected to different gate lines GL. In this case, on-off of the scan transistor SCT and on-off of the sensing transistor SENT may be controlled independently.

As another example, the gate node of the scan transistor SCT and the gate node of the sensing transistor SENT may be electrically connected to each other. That is, the gate node of the scan transistor SCT and the gate node of the sensing transistor SENT may be commonly connected to one gate line GL. In this case, the on-off of the scan transistor SCT and the on-off of the sensing transistor SENT may be controlled simultaneously.

Referring to FIG. 3, the driving transistor DRT, scan transistor SCT, and sensing transistor SENT may each be an n-type transistor or a p-type transistor. In this disclosure, for convenience of explanation, it is exemplified that the driving transistor DRT, scan transistor SCT, and sensing transistor SENT are each n-type.

The subpixel SP shown in FIG. 3 is only an example, and may be modified in various ways by including one or more transistors or one or more capacitors.

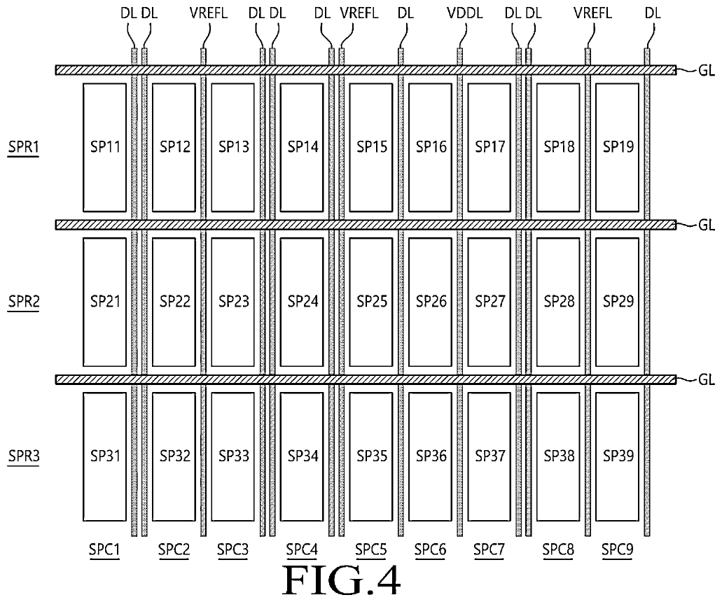

FIG. 4 is a plan view of a display panel 110 according to embodiments of the present disclosure.

Referring to FIG. 4, a plurality of subpixels SP disposed on the display panel 110 according to embodiments of the present disclosure may be arranged in a matrix form. For example, the plurality of subpixels SP disposed on the display panel 110 according to embodiments of the present disclosure may include 27 subpixels SP11 to SP19, SP21 to SP29 and SP31 to SP39 arranged in three rows and nine columns. The 27 subpixels SP11 to SP19, SP21 to SP29, and SP31 to SP39 may constitute the first to third subpixel rows SPR1 to SPR3. The 27 subpixels SP11 to SP19, SP21 to SP29, and SP31 to SP39 may constitute the first to ninth subpixel columns SPC1 to SPC9.

As an example, the plurality of subpixels SP disposed on the display panel 110 may include a red subpixel emitting red light, a green subpixel emitting green light, and a blue subpixel emitting blue light.

For example, in this case, subpixels arranged in the first, fourth, and seventh subpixel columns SPC1, SPC4, and SPC7 may be red subpixels. Subpixels arranged in the second, fifth, and eighth subpixel columns SPC2, SPC5, and SPC8 may be green subpixels. Subpixels arranged in the third, sixth, and ninth subpixel columns SPC3, SPC6, and SPC9 may be blue subpixels.

As an example, the plurality of subpixels SP disposed on the display panel 110 may include a red subpixel emitting red light, a green subpixel emitting green light, a blue subpixel emitting blue light, and a white subpixel emitting white light.

Referring to FIG. 4, the display panel 110 according to embodiments of the present disclosure may include vertical lines extending in the column direction and horizontal lines extending in the row direction. The horizontal and vertical lines may vary depending on the structure of the subpixel SP.

The horizontal lines may include the gate lines GL, and the vertical lines may include the data lines DL.

For example, in the case that the subpixel SP has the structure shown in FIG. 2, the horizontal lines may include scan signal lines as gate lines GL, and the vertical lines may include data lines DL and at least one first common driving voltage line VDDL.

As another example, if the subpixel SP is configured as the structure shown in FIG. 3, the horizontal lines may include gate lines GL, scan signal lines, and sensing signal lines, and the vertical lines may include data lines DL, at least one first common driving voltage line VDDL, and at least one reference voltage line VREFL.

FIG. 4 illustrates a signal line arrangement structure for a case in which the subpixel SP has the same structure as that of FIG. 3. The arrangement positions and numbers of the gate lines GL, data lines DL, at least one first common driving voltage line VDDL, and at least one reference voltage line VREFL illustrated in FIG. 4 may be modified in various ways.

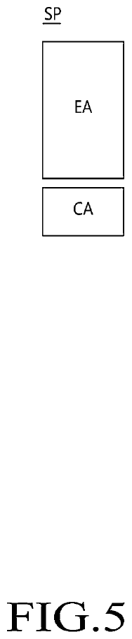

FIG. 5 illustrates an area of a subpixel of a display panel 110 according to embodiments of the present disclosure.

Referring to FIG. 5, in the case that the display panel 110 according to embodiments of the present disclosure emits light in a rear direction, the area of each subpixel SP may include a circuit area CA where the subpixel circuit SPC is disposed, and an emission area EA where light is emitted by the light emitting device ED.

In the case that the display panel 110 emits light in the rear direction, the circuit area CA and the emission area EA may not overlap each other. The emission area EA may be also referred to as an opening or aperture area.

Meanwhile, light generated from the emission layer EML of the light emitting device ED of the display panel 110 may pass through various components within the display panel 110 and comes out of the display panel 110. However, among the light generated in the emission layer EML of the light emitting device ED, there may be light that does not come out of the display panel 110 and is trapped inside the display panel 110.

Among the light generated in the emission layer EML of the light emitting device ED, the more light that does not come out of the display panel 110 and is trapped inside the display panel 110, the luminance of the corresponding subpixel SP may decrease. Accordingly, there may deteriorate the quality of the image displayed on the display panel 110.

Accordingly, the display panel 110 according to embodiments of the present disclosure may include a light extraction structure which allows a greater amount of light to be emitted toward the viewing surface among the light generated by the light emitting device ED.

The light extraction structure according to embodiments of the present disclosure may be a structure included in the display panel 110, and may reduce the amount of light trapped inside the display panel 110 among the amount of light generated from the emission layer EML of the light emitting device ED in the display panel 110 and increase the amount of light emitted to the outside of the display panel 110. “Light extraction” in the embodiments of the present disclosure may mean that a portion of the light emitted from the emission layer EML of the light emitting device ED in the display panel 110 is emitted to the outside of the display panel 110.

Hereinafter, it will be described a light extraction structure according to embodiments of the present disclosure in detail. In the following description, it is exemplified a case where the display panel 110 according to embodiments of the present disclosure has a bottom emission structure.

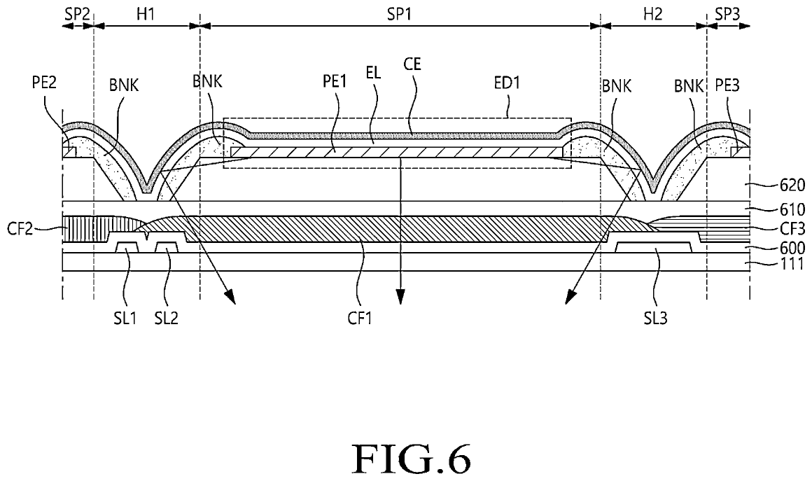

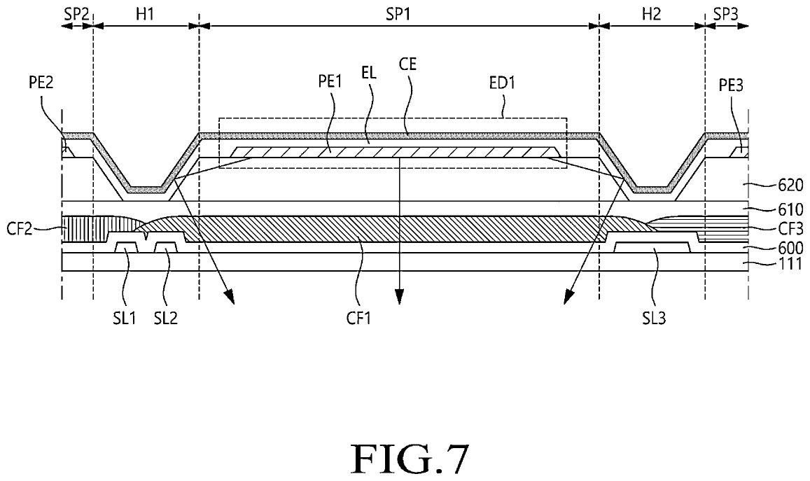

FIGS. 6 and 7 illustrate a light extraction structure of a display panel 110 according to embodiments of the present disclosure.

FIG. 6 illustrates a light extraction structure in the display panel 110 including a bank BNK, and FIG. 7 illustrates a light extraction structure in the display panel 110 without a bank BNK.

Referring to FIGS. 6 and 7, the display panel 110 may include a first subpixel SP1, a second subpixel SP2 on one side of the first subpixel SP1, and a third subpixel SP3 on the other side of the first subpixel SP1.

Referring to FIGS. 6 and 7, the display panel 110 according to embodiments of the present disclosure may include a substrate 111, a passivation layer 600 on the substrate 111, first to third color filters CF1, CF2 and CF3 on the passivation layer 600, a first protective layer 610 on the first to third color filters CF1, CF2 and CF3, a second protective layer 620 located on the first protective layer 610, first to third pixel electrodes PE1, PE2 and PE3 located on the second protective layer 620, an intermediate layer EL on the first to third pixel electrodes PE1, PE2 and PE3, and a common electrode CE on the intermediate layer EL.

Referring to FIGS. 6 and 7, the first to third pixel electrodes PE1, PE2 and PE3 may be transparent electrodes, and the common electrode CE may be a reflective electrode.

Referring to FIGS. 6 and 7, the display panel 110 according to embodiments of the present disclosure may include signal lines SL1, SL2 and SL3 located between the substrate 111 and the passivation layer 600. For example, the signal lines SL1, SL2 and SL3 may be vertical lines. For example, the vertical lines may include data lines DL, at least one first common driving voltage line VDDL, and at least one reference voltage line VREFL.

Referring to FIGS. 6 and 7, holes H1 and H2 may be formed between two adjacent subpixels (or two adjacent pixel electrodes) in the second protective layer 620. That is, the second protective layer 620 may include a first hole H1 formed between the first subpixel SP1 and the second subpixel SP2, a second hole H2 formed between the second subpixel SP2 and the third subpixel SP3.

Accordingly, the intermediate layer EL and the common electrode CE may be disposed inside the holes H1 and H2 along the sides of the holes H1 and H2 of the second protective layer 620. Accordingly, a portion of the common electrode CE disposed inside the holes H1 and H2 of the second protective layer 620 may be located closer to the substrate 111 than the pixel electrodes PE1, PE2 and PE3.

Therefore, the light emitted from the emission layer EML of the first light emitting device ED1 in the first subpixel SP1 may be reflected at the common electrode CE and may travel toward the viewing surface. Here, the emission layer EML of the first light emitting device ED1 may be a layer included in the intermediate layer EL, and may exist between the first pixel electrode PE1 and the common electrode CE (see FIG. 2).

Referring to FIG. 6, a bank BNK may be disposed between the pixel electrodes PE1, PE2 and PE3 and the intermediate layer EL. The bank BNK may be disposed to cover the ends of the pixel electrodes PE1, PE2 and PE3. In addition, the bank BNK may have grooves or holes formed inside the holes H1 and H2 of the second protective layer 620. Accordingly, a portion of the common electrode CE disposed inside the holes H1 and H2 of the second protective layer 620 may be located closer to the substrate 111 than the pixel electrodes PE1, PE2 and PE3.

Referring to FIG. 6, if a bank BNK exists, the sides of both ends of each pixel electrode PE1, PE2 and PE3 may have various shapes such as a reverse taper shape, a normal taper shape, or a vertical shape.

As shown in FIG. 7, the bank BNK may not exist.

Referring to FIG. 7, when the bank BNK does not exist, the side surfaces of both ends of each pixel electrode PE1, PE2, and PE3 may have a regular taper shape. As a result, it is possible to prevent charges from being concentrated on both ends of each pixel electrode PE1, PE2 and PE3.

In the case that the bank BNK does not exist, if the sides of both ends of each pixel electrode PE1, PE2 and PE3 have a reverse taper shape or vertical shape where sharp points may exist, the charges may be concentrated on both ends of each pixel electrode PE1, PE2 and PE3. If charges are concentrated on both ends (e.g., edges) of each pixel electrode PE1, PE2 and PE3, there may occur more severe deterioration in the portion adjacent to both ends of each pixel electrode PE1, PE2 and PE3 in the intermediate layer EL. As a result, the luminance of the outer portion of the emission area of each subpixel SP1, SP2, and SP3 may become abnormally low.

Therefore, in the case that the bank BNK does not exist, the sides of both ends of each pixel electrode PE1, PE2, and PE3 may have a regular taper shape, so that it is possible to prevent the phenomenon of electric charges being concentrated. As a result, it is possible to prevent the phenomenon in which the luminance of the outer portion of the emission area of each subpixel SP1, SP2 and SP3 becomes abnormally low or dark.

As described above, the light extraction structure of the display panel 110 according to embodiments of the present disclosure may have the following characteristics.

The insulating layer (e.g., the second protective layer 620 in FIGS. 6 and 7) located below the pixel electrode PE may have a step structure (e.g., a hole or groove in the insulating layer). The step structure of the insulating layer may be located between two adjacent pixel electrodes PE. That is, the step structure of the insulating layer may not overlap with the pixel electrode PE. In addition, the common electrode CE may be also disposed inside the hole or groove as the step structure of the insulating layer, so that the common electrode CE located inside the hole or groove of the insulating layer may be located lower than the emission layer EML or the pixel electrode PE.

According to the light extraction structure of the display panel 110 according to embodiments of the present disclosure, the light emitted from the emission layer EML of the light emitting device ED may be reflected by the common electrode CE located on the side of the pixel electrode PE and travel toward the viewing surface.

Accordingly, the ratio of light emitted to the outside of the display panel 110 among the light emitted from the emission layer EML of the light emitting device ED may increase. That is, light extraction performance may be increased.

The display panel 110 according to embodiments of the present disclosure may have a light extraction structure, thereby increasing light extraction efficiency. The light extraction efficiency may indicate a degree of the increase of the amount of light emitted outside the display panel 110 in a case having a light extraction structure compared to the amount of light emitted outside the display panel 110 in a case without light extraction structure.

A light extraction structure may be formed by forming a step structure of the second protective layer 620 between two adjacent emission areas (i.e., adjacent subpixels).

In the case that the display panel 110 is required to be designed as a high-resolution product, a gap between two adjacent emission areas (i.e., two adjacent subpixels) may become significantly narrowed. Accordingly, there may be insufficient space for a light extraction structure to be formed between two adjacent emission areas (i.e., two adjacent subpixels).

Accordingly, the display device 100 according to embodiments of the present disclosure may include a light extraction structure suitable for the high-resolution display panel 110. Hereinafter, it will be described in detail a light extraction structure suitable for the high-resolution display panel 110 according to embodiments of the present disclosure. Hereinafter, “light extraction structure suitable for the high-resolution display panel 110” is described as “light extraction structure for high-resolution.”

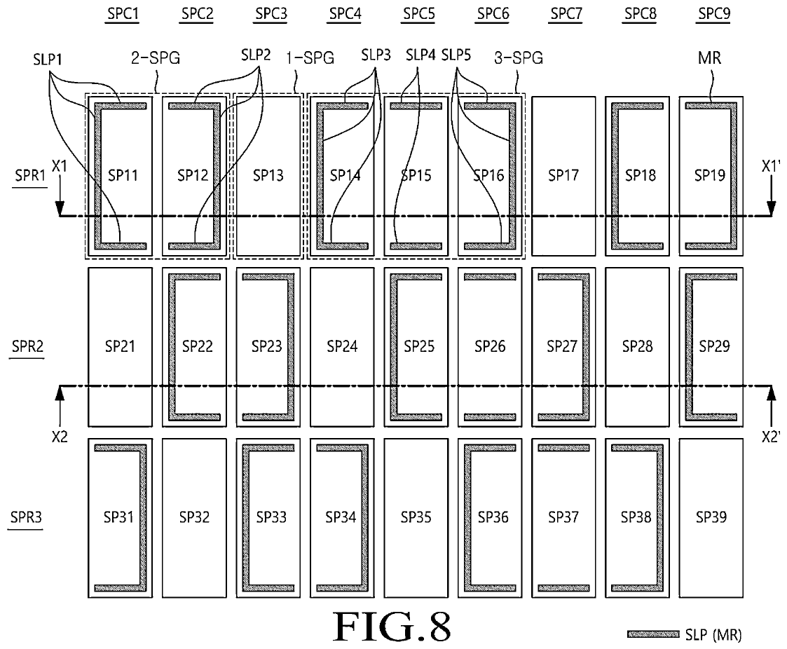

FIGS. 8, 9 and 10 illustrate a light extraction structure for high-resolution of the display panel 110 according to embodiments of the present disclosure.

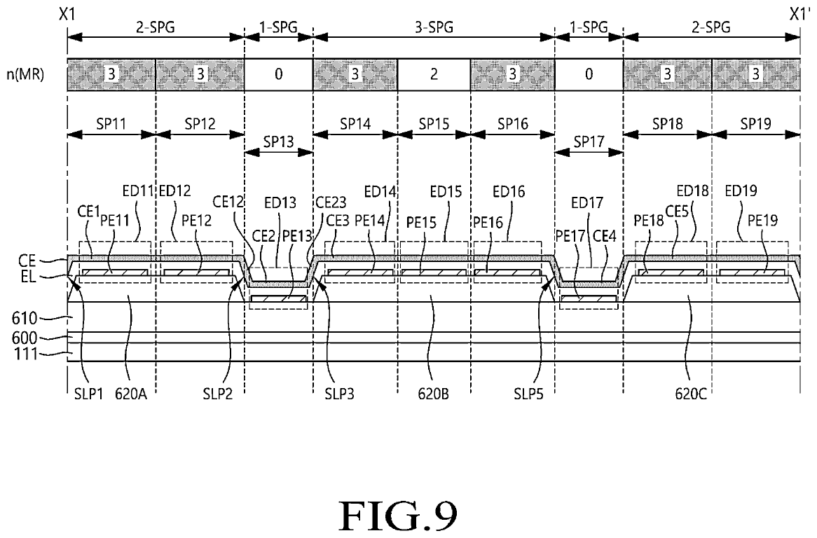

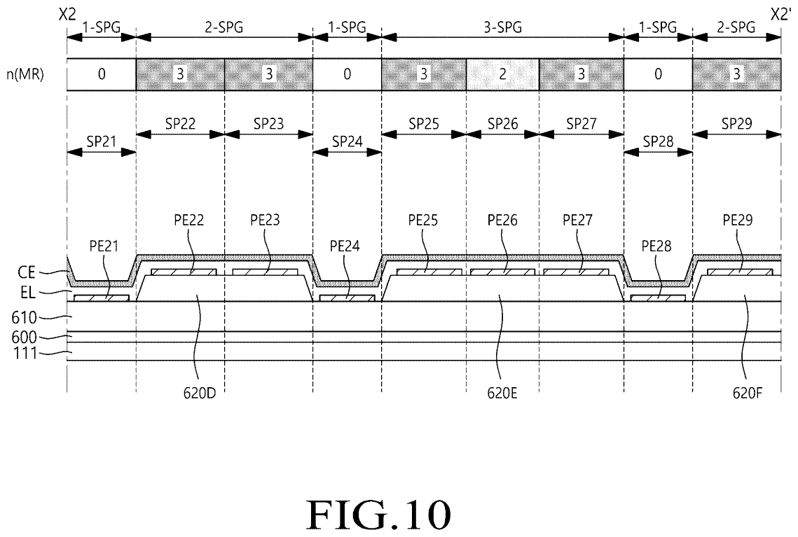

FIG. 8 is a plan view illustrating a light extraction structure suitable for high-resolution of the display panel 110 according to embodiments of the present disclosure, and FIGS. 9 and 10 are cross-sectional diagrams of a light extraction structure suitable for high-resolution of the display panel 110 according to embodiments of the present disclosure. FIG. 9 is a cross-sectional view along the line X1-X1′ in the plan view of FIG. 8, and FIG. 10 is a cross-sectional along the line X2-X2′ in the plan view of FIG. 8.

Referring to FIG. 8, the display panel 110 having a light extraction structure suitable for high-resolution according to embodiments of the present disclosure may include 27 subpixels SP11 to SP19, SP21 to SP29, and SP31 to SP39 arranged in three rows and nine columns. The 27 subpixels SP11 to SP19, SP21 to SP29, and SP31 to SP39 may constitute the first to third subpixel rows SPR1 to SPR3. The 27 subpixels SP11 to SP19, SP21 to SP29, and SP31 to SP39 may constitute the first to ninth subpixel columns SPC1 to SPC9. In FIG. 8, each of the 27 subpixels SP11 to SP19, SP21 to SP29, and SP31 to SP39 may mean a subpixel area.

In FIG. 8, for convenience of explanation, there are not illustrated various signal lines (e.g., DL, VDDL, REFL, GL) for driving the 27 subpixels SP11 to SP19, SP21 to SP29, and SP31 to SP39. In FIG. 8, the rectangles representing the 27 subpixels SP11 to SP19, SP21 to SP29, and SP31 to SP39 may represent the emission areas of the 27 subpixels SP11 to SP19, SP21 to SP29, and SP31 to SP39. In FIG. 8, the circuit areas of 27 subpixels SP11 to SP19, SP21 to SP29, and SP31 to SP39 are omitted.

In FIGS. 9 and 10, color filters disposed between the passivation layer 600 and the first protective layer 610 are omitted. Each color filter may be disposed to overlap with the corresponding pixel electrode (see FIGS. 6 and 7).

In addition, the display panel 110 according to embodiments of the present disclosure may have a structure with a bank BNK as shown in FIG. 6, or may have a structure without a bank BNK as shown in FIG. 7. Referring to FIGS. 9 and 10, when the bank BNK exists as shown in FIG. 6, the bank BNK may be disposed to partially cover both ends of each pixel electrode.

Referring to FIG. 8, a light extraction structure for high-resolution included in the display panel 110 according to embodiments of the present disclosure may include a mirror MR. The light extraction structure for high-resolution included in the display panel 110 according to embodiments of the present disclosure may include not only a structure referred to as a mirror MR, but also a number of mirrors n(MR) and a mirror arrangement structure.

The mirror MR for forming a light extraction structure for high-resolution according to embodiments of the present disclosure may be formed by an inclined surface SLP or a slope of the common electrode CE. In embodiments of the present disclosure, the inclined surface SLP of the common electrode CE may correspond to a step portion of the common electrode CE, and the inclined surface SLP of the common electrode CE may also be referred to as a mirror MR or a mirror surface.

In the light extraction structure for high-resolution according to embodiments of the present disclosure, the common electrode CE may have a plurality of inclined surfaces SLP. The inclined surface SLP of the common electrode CE may exist only in or around the areas of some subpixels, and the inclined surface SLP of the common electrode CE may not exist in or around the areas of other subpixels.

According to the example of FIG. 8, the inclined surface SLP of the common electrode CE corresponding to the mirror MR may exist only for some of the subpixels SP11, SP12, SP14, SP15, SP16, SP18, SP19, SP22, SP23, SP25, SP26, SP27, SP29, SP31, SP33, SP34, SP36, SP37, and SP38 among the 27 subpixels SP11 to SP19, SP21 to SP29, and SP31 to SP39.

According to the example of FIG. 8, the inclined surface SLP of the common electrode CE corresponding to the mirror MR may not exist for the other subpixels SP13, SP17, SP21, SP24, SP28, SP32, SP35, SP39 among the 27 subpixels SP11 to SP19, SP21 to SP29, and SP31 to SP39.

For example, in a light extraction structure for high-resolution according to embodiments of the present disclosure, the number of inclined surfaces SLP of the common electrode CE existing in or around the area of some subpixels may be different from the number of inclined surfaces SLP of the common electrode CE existing in or around the area of some other subpixels.

As another example, in the light extraction structure for high-resolution according to embodiments of the present disclosure, a location of inclined surfaces SLP of the common electrode CE existing in or around the area of some subpixels may be different from a location of inclined surfaces SLP of the common electrode CE existing in or around the area of some other subpixels.

It will be described a light extraction structure suitable for high-resolution according to embodiments of the present disclosure in more detail with reference to FIG. 8.

Referring to FIG. 8, each of the first to third subpixel rows SPR1, SPR2 and SPR3 may include a first subpixel group 1-SPG including K subpixels, a second subpixel group 2-SPG including N subpixels, and a third subpixel group 3-SPG including M subpixels.

The K may be a natural number greater than 1, the N may be a natural number greater than 2, and the M may be a natural number greater than 2. In the example of FIG. 8, K is 1, N is 2, and M is 3.

Hereinafter, it will be described the number of mirror n(MR) and mirror arrangement structure as a light extraction structure for high-resolution included in the display panel 110 according to embodiments of the present disclosure base on a case where K is 1, N is 2, and M is 3.

Referring to FIGS. 8 and 9, in the first subpixel row SPR1, light emitted from one subpixel SP13 and SP17 included in the first subpixel group 1-SPG may be emitted directly to the outside of the display panel 110 without being reflected in the mirror MR. That is, the number n(MR) of mirrors MR located around the light emitting device of one subpixel SP13 and SP17 included in the first subpixel group 1-SPG may be 0.

Referring to FIGS. 8 and 9, in the first subpixel row SPR1, the light emitted from each of the two subpixels SP11/SP12 and SP18/SP19 included in the second subpixel group 2-SPG may be reflected by the three mirrors MR and emitted to the outside of the display panel 110. That is, the number n(MR) of mirrors MR located around the light emitting devices of each of the two subpixels SP11/SP12 and SP18/SP19 included in the second subpixel group 2-SPG may be three.

Referring to FIGS. 8 and 9, in the first subpixel row SPR1, the light emitted from a subpixel SP15 located in the middle of the three subpixels SP14/SP15/SP16 included in the third subpixel group 3-SPG may be reflected by the two mirrors MR and emitted to the outside of the display panel 110. That is, the number n(MR) of mirrors MR located around the light emitting device of the middle subpixel SP15 among the three subpixels SP14/SP15/SP16 included in the third subpixel group 3-SPG may be two.

Referring to FIGS. 8 and 9, in the first subpixel row SPR1, the light emitted from each of the two subpixels SP14/SP16 located on the left and right among the three subpixels SP14/SP15/SP16 included in the third subpixel group 3-SPG may be reflected by the three mirrors MR and be emitted to the outside of the display panel 110. That is, the number n(MR) of mirrors MR located around the light emitting device of each of the two subpixels SP14/SP16 located on the left and right among the three subpixels SP14/SP15/SP16 included in the third subpixel group 3-SPG may be three.

Referring to FIGS. 8 and 10, in the second subpixel row SPR2, light emitted from one subpixel SP21 SP24 or SP28 included in the first subpixel group 1-SPG may be emitted directly to the outside of the display panel 110 without being reflected by the mirror MR. That is, the number n(MR) of mirrors MR located around the light emitting device of one subpixel SP21, SP24 or SP28 included in the first subpixel group 1-SPG may be zero.

Referring to FIGS. 8 and 10, in the second subpixel row SPR2, the light emitted from each of the two subpixels SP22/SP23 included in the second subpixel group 2-SPG may be reflected by the three mirrors MR and emitted to the outside of the display panel 110. That is, the number n(MR) of mirrors MR located around the light emitting devices of each of the two subpixels SP22/SP23 included in the second subpixel group 2-SPG may be three.

Referring to FIGS. 8 and 10, in the second subpixel row SPR2, light emitted from the subpixel SP26 located in the middle of the three subpixels SP25/SP26/SP27 included in the third subpixel group 3-SPG may be reflected by the two mirrors MR and emitted to the outside of the display panel 110. That is, the number n(MR) of mirrors MR located around the light emitting device of the middle subpixel SP26 among the three subpixels SP25/SP26/SP27 may be two.

Referring to FIGS. 8 and 10, in the second subpixel row SPR2, light emitted from each of the two subpixels SP25/SP27 located on the left and right among the three subpixels SP25/SP26/SP27 included in the third subpixel group 3-SPG may be reflected by the three mirrors MR and be emitted to the outside of the display panel 110. That is, the number n(MR) of mirrors MR located around the light emitting device of each of the two subpixels SP25/SP27 located on the left and right among the three subpixels SP25/SP26/SP27 included in the third subpixel group 3-SPG may be three.

Referring to FIG. 8, in the third subpixel row SPR3, light emitted from one subpixel SP32, SP35 or SP39 included in the first subpixel group 1-SPG may be emitted directly to the outside of the display panel 110 without being reflected by a mirror MR. That is, the number n(MR) of mirrors MR located around the light emitting device of one subpixel SP32, SP35 or SP39 included in the first subpixel group 1-SPG may be zero.

Referring to FIG. 8, in the third subpixel row SPR3, light emitted from each of the two subpixels SP33/SP34 included in the second subpixel group 2-SPG may be reflected from three mirrors MR and emitted to the outside of the display panel 110. That is, the number n(MR) of mirrors MR located around the light emitting devices of each of the two subpixels SP33/SP34 included in the second subpixel group 2-SPG may be three.

Referring to FIG. 8, in the third subpixel row SPR3, a the light emitted from a middle subpixel SP37 among the three subpixels SP36/SP37/SP38 included in the third subpixel group 3-SPG may be reflected by the two mirrors MR and be emitted to the outside of the display panel 110. That is, the number n(MR) of mirrors MR located around the light emitting device of the middle subpixel SP37 among the three subpixels SP36/SP37/SP38 included in the third subpixel group 3-SPG may be two.

Referring to FIG. 8, in the third subpixel row SPR3, the light emitted from each of two subpixels SP36/SP38 located on the left and right among the three subpixels SP36/SP37/SP38 included in the third subpixel group 3-SPG may be reflected by the three mirrors MR and emitted to the outside of the display panel 110. That is, the number of n(MR mirrors MR located around the light emitting device of each of the two subpixels SP36/SP38 located on the left and right among the three subpixels SP36/SP37/SP38 included in the third subpixel group 3-SPG may be three.

Referring to FIGS. 9 and 10, the display panel 110 according to embodiments of the present disclosure may include a substrate 111, a first protective layer 610 located on the substrate 111, the insulating layers 620A, 620B, 620C, 620D, 620E and 620F on the first protective layer 610, the light emitting devices ED11, ED12, ED14, ED15, ED16, ED18, ED19, ED22, ED23, ED25, ED26, ED27 and ED29 on the insulating layers 620A, 620B, 620C, 620D, 620E and 620F, and the light emitting devices ED13, ED17, ED21, ED24 and ED28 on the first protective layer 610.

Referring to FIGS. 8, 9, and 10, in the display panel 110 according to embodiments of the present disclosure, in order to form a light extraction structure for high-resolution, the common electrode CE may have inclined surfaces SLP corresponding to the mirror MR on each side of the insulating layers 620A, 620B, 620C, 620D, 620E, and 620F.

For example, the common electrode CE may have inclined surfaces SLP on four sides of each of the insulating layers 620A, 620B, 620C, 620D, 620E, and 620F.

As an example, the common electrode CE may have four inclined surfaces SLP on four sides of the first insulating layer 620A. Accordingly, among the two first light emitting devices ED11 and ED12 on the first insulating layer 620A, three first inclined surfaces SLP1 of the common electrode CE may be formed at three of the four sides (e.g., upper side, lower side, left side) of the first light emitting device ED11 located on the left side, and there may be three second inclined surfaces SLP2 of the common electrode CE at three of the four sides (e.g., upper side, lower side, right side) of the first light emitting device ED12 located on the right.

In this case, there may mean that, among the two first light emitting devices ED11 and ED12 on the first insulating layer 620A, the first subpixel SP11 including the first light emitting device ED11 located on the left has three mirrors MR, and the first subpixel SP12 including the first light emitting device ED12 located on the right has three mirrors MR.

As another example, the common electrode CE may have four inclined surfaces SLP on the four sides of the second insulating layer 620B. Accordingly, among the three third light emitting devices ED14, ED15 and ED16 on the second insulating layer 620B, there may be three third inclined surfaces SLP3 of the common electrode CE on three of the four sides (e.g., upper side, lower side, on the left side) of the third light emitting device ED14 located on the left, two fourth inclined surfaces SLP4 of the common electrode CE may exist on two of the four sides (e.g., upper side, lower side) of the third light emitting device ED15 located in the middle, and three fifth inclined surfaces SLP5 of the common electrode CE may exist on three of the four sides (e.g., upper side, lower side, right side) of the third light emitting device ED16 located on the right.

In this case, there may mean that, among the three third light emitting devices ED14, ED15 and ED16 on the second insulating layer 620B, the third subpixel SP14 including the third light emitting device ED14 located on the left has three mirrors MR, and the third subpixel SP15 including the third light emitting device ED15 located in the middle has two mirrors MR, and the third subpixel SP16 including the third light emitting device ED16 located on the right has three mirrors MR.

Referring to FIG. 9, the common electrode CE may include an inclined surface SLP2 which extends from the top of the first pixel electrode PE12, passes through one side of the first pixel electrode PE12, and extends to the top of the second pixel electrode PE13, and an inclined surface SLP3 which extends from the top of the third pixel electrode PE14, passes through the other side of the third pixel electrode PE14, and extends to the top of the second pixel electrode PE13.

With reference to FIG. 9, it will be examined in more detail a vertical structure of the light extraction structure for high-resolution according to embodiments of the present disclosure.

The display panel 110 according to embodiments of the present disclosure may include a substrate 111, a first protective layer 610 located on the substrate 111, the insulating layers 620A, 620B and 620C on the first protective layer 610, the light emitting devices ED11, ED12, ED14, ED15, ED16, ED18 and ED19 located on the insulating layers 620A, 620B and 620C and arranged in a first subpixel row SPR1, and the light emitting devices ED13 and ED17 located on the first protective layer 610 and arranged in the first subpixel row SPR1.

Referring to FIG. 9, the insulating layers 620A, 620B and 620C on the first protective layer 610 may include a first insulating layer 620A, a second insulating layer 620B, and a third insulating layer 620C.

The first insulating layer 620A, the second insulating layer 620B, and the third insulating layer 620C may be insulating layers in which the second protective layer 620 of FIGS. 6 and 7 is patterned. The first insulating layer 620A, the second insulating layer 620B, and the third insulating layer 630B may be made of the same insulating material which forms the second protective layer 620 in FIGS. 6 and 7.

Each of the first insulating layer 620A, the second insulating layer 620B, and the third insulating layer 620C may be an organic layer containing an organic material. Each of the first insulating layer 620A, the second insulating layer 620B, and the third insulating layer 620C may have a flat top surface. The first insulating layer 620A, the second insulating layer 620B, and the third insulating layer 620C may be insulating layers formed together during the process. The first insulating layer 620A, the second insulating layer 620B, and the third insulating layer 620C may be layers of the same insulating material and may be separated from each other in an island shape. That is, the first insulating layer 620A, the second insulating layer 620B, and the third insulating layer 620C may be spaced apart from each other.

Referring to FIG. 9, the light emitting devices ED11, ED12, ED14, ED15, ED16, ED18 and ED19 on the insulating layers 620A, 620B and 620C may include light emitting devices ED11 and ED12 on the first insulating layer 620A, light emitting devices ED14, ED15 and ED16 on the second insulating layer 620B, and light emitting devices ED18 and ED19 on the third insulating layer 620C.

Referring to FIG. 9, the light emitting devices ED13 and ED17 on the first protective layer 610 may include a light emitting device ED13 located on the first protective layer 610 and between the first insulating layer 620A and the second insulating layer 620B, and a light emitting device ED17 located on the first protective layer 610 and between the second insulating layer 620B and the third insulating layer 620C.

The light emitting devices ED11, ED12, ED13, ED14, ED15, ED16, ED17, ED18, and ED19 shown in FIG. 9 may be included in the subpixels SP11, SP12, SP13, SP14, SP15, SP16, SP17, SP18 and SP19 arranged in the first subpixel row SPR1 of FIG. 8.

Referring to FIGS. 8 and 9, the subpixels SP11, SP12, SP13, SP14, SP15, SP16, SP17, SP18 and SP19 arranged in the first subpixel row SPR1 may include N first subpixels (e.g. SP11/SP12, SP18/SP19 when N=2), K second subpixels (e.g., SP13, SP17 when K=1), and M third subpixels (e.g., SP14/SP15/SP16 when M=3).

In the light extraction structure for high-resolution according to embodiments of the present disclosure, N may be a natural number of 2 or more, K may be a natural number of 1 or more, and M may be a natural number of 2 or more. According to the examples of FIGS. 8 and 9, N may be 2, K may be 1, and M may be 3.

Referring to FIG. 9, the N first subpixels SP11 and SP12 may include N first pixel electrodes PE11 and PE12 disposed on the first insulating layer 620A.

The K second subpixels SP13 may include K second pixel electrodes PE13 disposed on the first protective layer 610 located below the first insulating layer 620A.

The M third subpixels SP14, SP15 and SP16 may include M third pixel electrodes PE14, PE15 and PE16 disposed on the second insulating layer 620B.

Referring to FIG. 9, the first insulating layer 620A may be located on the first protective layer 610, and may be disposed in the area of the N first subpixels SP11 and SP12.

The second insulating layer 620B may be located on the first protective layer 610, and may be disposed in the area of the M third subpixels SP14, SP15, and SP16.

Referring to FIG. 9, N first pixel electrodes PE11 and PE12 may be located on the first insulating layer 620A, and may be included in N first subpixels SP11 and SP12.

The K second pixel electrodes PE13 may be located on the first protective layer 610, may be disposed between one side of the first insulating layer 620A and the other side of the second insulating layer 620B, and may be included in K second subpixel SP13.

The M third pixel electrodes PE14, PE15 and PE16 may be located on the second insulating layer 620B, and may be included in the M third subpixels SP14, SP15 and SP16.

Referring to FIG. 9, the intermediate layer EL may be disposed on the N first pixel electrodes PE11 and PE12, the K second pixel electrodes PE13, and the M third pixel electrodes PE14, PE15 and PE16. The common electrode CE may be located on the intermediate layer EL. As an example, the common electrode CE may be a reflective electrode. That is, the common electrode CE may include a reflective electrode material.

The intermediate layer EL may include light emission layers EML and a common intermediate layer EL_COM. The emission layers EML may be disposed to overlap each of the N first pixel electrodes PE11 and PE12, the K second pixel electrodes PE13, and the M third pixel electrodes PE14, PE15 and PE16. The common intermediate layer EL_COM may include a first common intermediate layer COM1 and a second common intermediate layer COM2. The first common intermediate layer COM1 may be commonly disposed between the N first pixel electrodes PE11 and PE12, the K second pixel electrodes PE13, and M third pixel electrodes PE14, PE15 and PE16. The second common intermediate layer COM2 may be commonly disposed between (N+K+M) emission layers EML and the common electrode CE.

Referring to FIG. 9, the K second pixel electrodes PE13 may be located closer from the substrate 111 than the N first pixel electrodes PE11 and PE12, and the M third pixel electrodes PE14, PE15 and PE16. That is, the N first pixel electrodes PE11 and PE12, and the M third pixel electrodes PE14, PE15 and PE16 may be located higher from the substrate 111 than the K second pixel electrodes PE13.

Referring to FIG. 9, the common electrode CE may include a first common electrode part CE1 located on the first insulating layer 620A, a second common electrode part CE2 disposed between one side of the first insulating layer 620A and the other side of the second insulating layer 620B and located on the first protective layer 610, and a third common electrode part CE3 located on the second insulating layer 620B.

The second common electrode part CE2 may be located closer to the substrate 111 than the first common electrode part CE1 and the third common electrode part CE3. The second common electrode part CE2 may be located farther from the substrate 111 than the K second pixel electrodes PE13. The second common electrode part CE2 may be located closer to the substrate 111 than the N first pixel electrodes PE11 and PE12 and the M third pixel electrodes PE14, PE15, and PE16.

Referring to FIG. 9, the common electrode CE may include a first connection part CE12 connecting the first common electrode part CE1 and the second common electrode part CE2, and a second connection part CE13 connecting and a second common electrode part CE2 and the third common electrode part CE3.

Referring to FIG. 9, the first connection part CE12 and the second connection part CE13 of the common electrode CE may be formed to be inclined. The first connection part CE12 may have an inclined surface SLP2, and the second connection part CE13 may have an inclined surface SLP3.

Referring to FIGS. 8 and 9, the first connection part CE12 and the second connection part CE13 of the common electrode CE may be mirrors MR to increase light extraction efficiency. The light emitted from the light emitting device ED12 on the first insulating layer 620A and the light emitted from the light emitting device ED14 on the second insulating layer 620B may be reflected from the first connection part CE12 and the second connection part CE13 of the common electrode CE and travel toward the viewing surface (e.g., rear or back of the substrate 111).

The light extraction structure in a second subpixel row SPR2 will be described with reference to FIG. 10. The light extraction structure in the second subpixel row SPR2 may be basically the same as the light extraction structure in the first subpixel row SPR1.

Referring to FIG. 10, the second subpixel row SPR2 may include nine subpixels SP21, SP22, SP23, SP24, SP25, SP26, SP27, SP28, and SP29.

The second subpixel row SPR2 may include N fourth subpixels SP22 and SP23, K fifth subpixels SP24, and M sixth subpixels SP25, SP26 and SP27. The N may be a natural number of 2 or more, K may be a natural number of 1 or more, and M may be a natural number of 2 or more. In the examples of FIGS. 8 and 9, N may be 2, K may be 1, and M may be 3.

Referring to FIG. 10, insulating layers 620D, 620E, and 620F which are spaced apart from each other may be disposed in the area of the second subpixel row SPR2.

The insulating layers 620D, 620E, and 620F disposed in the area of the second subpixel row SPR2 may include a fourth insulating layer 620D located on the first protective layer 610 and disposed in the area of the N fourth subpixels SP22 and SP23, ad a fifth insulating layer 620E located on the first protective layer 610 and disposed in the area of the M sixth subpixels SP25, SP26 and SP27.

Referring to FIG. 10, the second subpixel row SPR2 may include nine pixel electrodes PE21, PE22, PE23, PE24, PE25, PE26, PE27, PE8 and PE29 included in nine subpixels SP21, SP22, SP23, SP24, SP25, SP26, SP27, SP28, and SP29.

Referring to FIG. 10, the nine pixel electrodes PE21, PE22, PE23, PE24, PE25, PE26, PE27, PE8 and PE29 included in the second subpixel row SPR2 may include N fourth pixel electrodes PE22 and PE23 located on the fourth insulating layer 620D and included in N fourth subpixels SP22 and SP23, K fifth pixel electrodes PE24 which is located on the first protective layer 610, between one side of the fourth insulating layer 620D and the other side of the fifth insulating layer 620E, and is included in the K fifth subpixels SP24, and M sixth pixel electrodes PE25, PE26 and PE27 located on the fifth insulating layer 620E and included in the M sixth subpixels SP25, SP26 and SP27.

Referring to FIGS. 8, 9, and 10, the N first subpixels SP11 and SP12 may be arranged in the first to Nth subpixel columns (e.g., SPC1, SPC2 when N=2), respectively. The N fourth subpixels SP22, SP23 may be arranged in the second to (N+1)th subpixel columns (e.g., SPC2, SPC3 when N=2) shifted by one subpixel width, respectively.

Referring to FIG. 10, the fourth insulating layer 620D and the fifth insulating layer 620E may be layers of the same insulating material, and may be separated from each other in an island shape.

Referring to FIGS. 8, 9, and 10, the insulating layers 620A, 620B, and 620C may be disposed in the first subpixel row SPR1, and the insulating layers 620D, 620E, and 620F may be disposed in the second subpixel row SPR2.

According to the examples of FIGS. 8 and 9, N may be 2, K may be 1, and M may be 3.

Referring to FIGS. 8 and 9, the first subpixel row SPR1 may include two first subpixels SP11 and SP12, one second subpixel SP13, and three third subpixels SP14, SP15 and SP16.

Referring to FIGS. 8 and 9, the two first subpixels SP11 and SP12 may include two first pixel electrodes PE11 and PE12 on the first insulating layer 620A, respectively. The one second subpixel SP13 may include one second pixel electrode PE13 on the first protective layer 610. The three third subpixels SP14, SP15, and SP16 may each include three third pixel electrodes PE14, PE15 and PE16 on the second insulating layer 620B.

Referring to FIGS. 8 and 9, the common electrode CE may include three first inclined surfaces SLP1 located on three of the four sides of the first subpixel SP11 located on the left of the two first subpixels SP11 and SP12, three second inclined surfaces SLP2 located on three of the four sides of the first subpixel SP12 located on the right of the two first subpixels SP11 and SP12, three third inclined surfaces SLP3 located on three of the four sides of the third subpixel SP14 located on the left among the three third subpixels SP14, SP15 and SP16, two fourth inclined surfaces SLP4 located on two of the four sides of the third subpixel SP15 located in the middle of the three third subpixels SP14, SP15 and SP16, and three fifth inclined surfaces SLP5 located on three of the four sides of the third subpixel SP16 located on the right among the three third subpixels SP14, SP15 and SP16.

Referring to FIGS. 8 and 9, three first inclined surfaces SLP1 and three second inclined surfaces SLP2 may be formed on the side of the first insulating layer 620A. Three third inclined surfaces SLP3, two fourth inclined surfaces SLP4, and three fifth inclined surfaces SLP5 may be formed on the side of the second insulating layer 620B.

Referring to FIGS. 8 and 9, three first inclined surfaces SLP1, three second inclined surfaces SLP2, three third inclined surfaces SLP3, two fourth inclined surfaces SLP4, and three fifth inclined surfaces SLP5 may be a mirror MR for improving light extraction efficiency.

Referring to FIGS. 8 and 9, the number of inclined surfaces formed around one subpixel may be defined as the number of mirrors n(MR) of one subpixel.

Light emitted from the first subpixel SP11 located on the left of the two first subpixels SP11 and SP12 may be reflected by the three first inclined surfaces SLP1.

Light emitted from the first subpixel SP12 located on the right of the two first subpixels SP11, SP12 may be reflected by the three second inclined surfaces SLP2.

Light emitted from the third subpixel SP14 located on the left among the three third subpixels SP14, SP15 and SP16 may be reflected by the three third inclined surfaces SLP3.

Light emitted from the third subpixel SP15 located in the middle among the three third subpixels SP14, SP15 and SP16 may be reflected by the two fourth inclined surfaces SLP4.

Light emitted from the third subpixel SP16 located on the right among the three third subpixels SP14, SP15 and SP16 may be reflected by the three fifth inclined surfaces SLP5.

Referring to FIGS. 8 and 9, according to the light extraction structure for high-resolution according to the embodiments of the present disclosure, insulating layers 620A, 620B, and 620C disposed on the first protective layer 610 may be spaced apart from each other. In addition, in the area where the insulating layers 620A, 620B and 620C are spaced apart, the common electrode CE may include the connection parts CE12 and CE13 which connect flat common electrode parts CE1, CE2 and CE3, and have inclined surfaces SLP2 and SLP3. The connection parts CE12 and CE13 of the common electrode CE may correspond to the mirror MR which reflects light. Accordingly, light extraction efficiency can be improved.

The light extraction efficiency may vary depending on the number n(MR) of mirrors MR present around the light emitting device. The number of mirrors n(MR) may be the number of connection parts of the common electrode CE existing around one subpixel (i.e., a light emitting device in one subpixel), and may be the number of inclined surfaces SLP (i.e., inclined surfaces of connection parts) of the common electrode CE existing around one subpixel (i.e., a light emitting device in one subpixel).

According to the light extraction structure for high-resolution according to embodiments of the present disclosure, one or more mirrors MR exist around one subpixel, so that the light extraction efficiency of the corresponding subpixel can be increased.

In addition, according to the light extraction structure for high-resolution according to the embodiments of the present disclosure, the mirrors MR included in the light extraction structure may be formed in units of N or M subpixels instead of forming a mirror MR included in the light extraction structure between two adjacent light-emitting devices. Accordingly, the space for forming the light extraction structure may be reduced, which may help implement the high-resolution display panel 110.

Meanwhile, if the number of mirrors n(MR) around the light emitting device of one subpixel increases, the light extraction efficiency of one subpixel may increase. For example, if the number of mirrors n(MR) around the light emitting device of the first subpixel is 0, the light extraction efficiency of the first subpixel may be a reference efficiency value (e.g., 0(%)). If the number of mirrors n(MR) around the light emitting device of the first subpixel is 2, the light extraction efficiency of the first subpixel may be a first efficiency value (e.g., 10(%)). If the number of mirrors n(MR) around the light emitting device of the first subpixel is 3, the light extraction efficiency of the first subpixel may be a second efficiency value (e.g., 15(%)). Hereinafter, for convenience of explanation, it will be exemplified an example where the reference efficiency value is 0(%), the first efficiency value is 10(%), and the second efficiency value is 20(%).

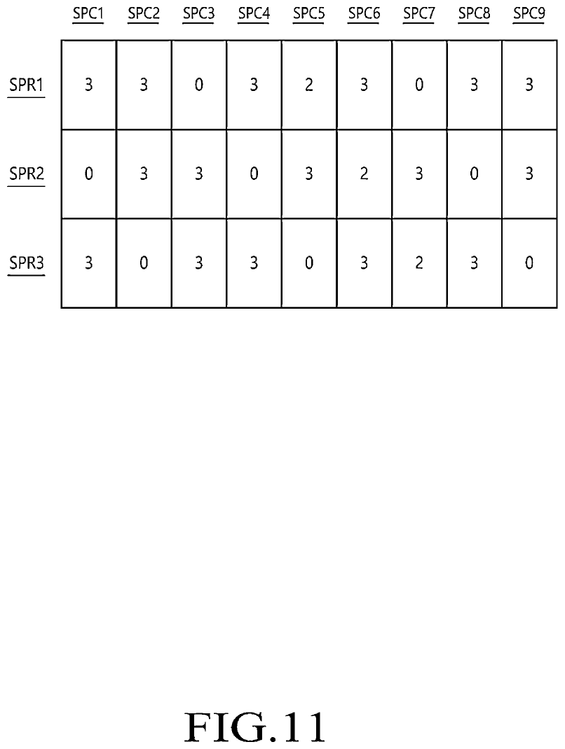

Hereinafter, for example, in the case of N=2, K=1, and M=3, a light extraction structure for high-resolution according to embodiments of the present disclosure is exemplarily illustrated with reference to FIGS. 11 to 13. Explain. However, in the following description, it will be also referred to FIGS. 8, 9, and 10 together.

FIG. 11 illustrates the number of mirrors n(MR) per subpixel of the display panel 110 according to embodiments of the present disclosure.

Referring to FIG. 11, the number of mirrors n(MR) for each of the two subpixels SP11/SP12, SP18/SP19 and SP22/SP23, SP33/SP34 included in each second subpixel group 2-SPG is three.

Among the three subpixels SP14/SP15/SP16, SP25/SP26/SP27 and SP36/SP37/SP38 included in each third subpixel group 3-SPG, one subpixel SP15, SP26 and SP37 located in the center may have the number of mirrors n(MR) of two, and the number of mirrors n(MR) of each of the two subpixels SP14/SP16, SP25/SP27 and SP36/SP38 located on the left and right may be three.

The number of mirrors n(MR) of each subpixel SP13, SP17, SP21, SP24, SP28, SP32, SP35 and SP39 included in each first subpixel group 1-SPG may be zero.

Referring to FIG. 11, the number of mirrors n(MR) of each of the nine subpixels SP11 to SP19 arranged in the first subpixel row SPR1 may be 3, 3, 0, 3, 2, 3, 0, 3, 3. The number of mirrors n(MR) of each of the nine subpixels SP21 to SP29 arranged in the second subpixel row SPR2 may be 0, 3, 3, 0, 3, 2, 3, 0, 3. The number of mirrors n(MR) of each of the nine subpixels SP31 to SP39 arranged in the third subpixel row SPR3 may be 3, 0, 3, 3, 0, 3, 2, 3, 0.

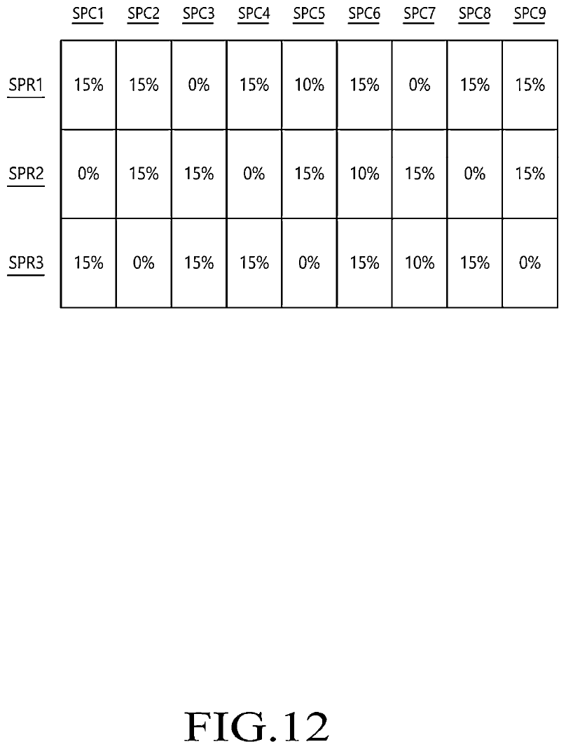

FIG. 12 illustrates light extraction efficiency for each subpixel of the display panel 110 according to embodiments of the present disclosure.

Referring to FIG. 12, if the number of mirrors n(MR) around the light emitting device is 0, the corresponding subpixels SP13, SP17, SP21, SP24, SP28, SP32, SP35 and SP39 may have the light extraction efficiency of 0%. If the number of mirrors n(MR) around the light emitting device is 2, the light extraction efficiency for the corresponding subpixels SP15, SP26 and SP37 may be 10%. If the number of mirrors n(MR) around the light emitting device is 3, the light extraction efficiency for the corresponding subpixels SP11, SP12, SP14, SP16, SP18, SP19, SP22, SP23, SP25, SP27, SP29, SP31, SP33, SP34, SP36 and SP38 may be 15%.

According to the light extraction structure for high-resolution according to the embodiments of the present disclosure, the light extraction efficiency may indicate a degree of the increase of the amount of light emitted outside the display panel 110 in a case with mirrors MR of the corresponding number of mirrors n(MR), compared to the amount of light emitted outside the display panel 110 in a case without a mirror MR.

Referring to FIG. 12, the light extraction efficiency of each of the nine subpixels SP11 to SP19 arranged in the first subpixel row SPR1 may be 15%, 15%, 0%, 15%, 10%, 15%, 0%, 15%, 15%. The light extraction efficiency of each of the nine subpixels SP21 to SP29 arranged in the second subpixel row SPR2 may be 0%, 15%, 15%, 0%, 15%, 10%, 15%, 0%, 15%. The light extraction efficiency of each of the nine subpixels SP31 to SP39 arranged in the third subpixel row SPR3 may be 15%, 0%, 15%, 15%, 0%, 15%, 10%, 15%, 0%.

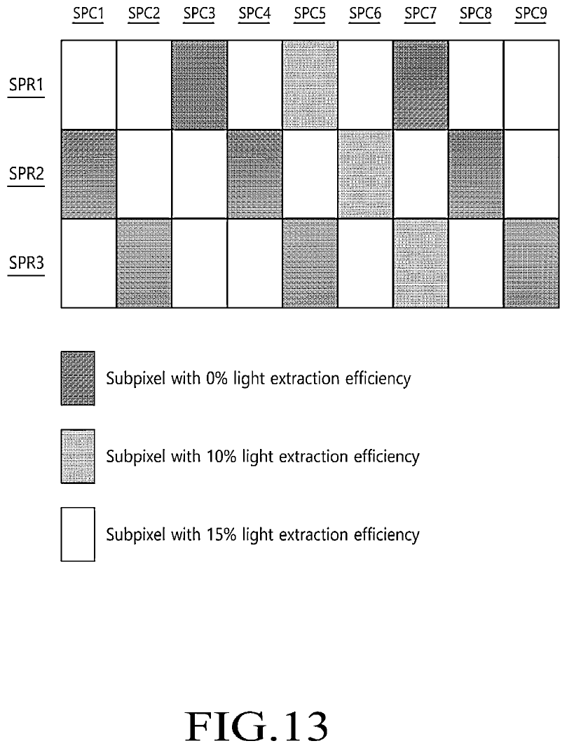

FIG. 13 illustrates the light emission state for each subpixel of the display panel according to embodiments of the present disclosure.

Referring to FIGS. 12 and 13, even if the same data voltage VDATA is supplied to 29 subpixels SP11 to SP19, SP21 to SP29 and SP31 to SP39, the larger the number of mirrors n(MR) in a subpixel and the higher the light extraction efficiency, the brighter the luminance of the subpixel may be.

Referring to FIGS. 12 and 13, even if the same data voltage VDATA is supplied to 29 subpixels SP11 to SP19, SP21 to SP29, and SP31 to SP39, an emission luminance of the subpixels having a light extraction efficiency of 15%, an emission luminance of subpixels with a light extraction efficiency of 10%, and an emission luminance of subpixels with a light extraction efficiency of 0% may be different from each other due to differences in light extraction structures (e.g., the number of mirrors, light extraction efficiency).

Referring to FIGS. 12 and 13, even if the same data voltage VDATA is supplied to 29 subpixels SP11 to SP19, SP21 to SP29 and SP31 to SP39, the emission luminance of subpixels with a light extraction efficiency of 15% may be the brightest, and the emission luminance of subpixels with a light extraction efficiency of 0% may be the darkest. The emission luminance of subpixels with a light extraction efficiency of 10% may be between the emission luminance of subpixels with a light extraction efficiency of 0% and the emission luminance of subpixels with a light extraction efficiency of 15%.

According to the light extraction structure for high-resolution according to the embodiments of the present disclosure, there may be no mirror MR around the light emitting device of some subpixels, and the number of mirrors n(MR) for each subpixel may be different from each other.

Therefore, even if the same data voltage VDATA is supplied to a plurality of subpixels SP11 to SP19, SP21 to SP29, and SP31 to SP39, emission luminance of some subpixels of the plurality of subpixels SP11 to SP19, SP21 to SP29, and SP31 to SP39 may be different from that of other subpixels. This deviation in luminance may cause spots on the display screen.

The light extraction structure for high-resolution according to embodiments of the present disclosure may effectively increase light extraction efficiency while reducing the area where the light extraction structure is formed in the display panel 110. However, in the case of a light extraction structure for high-resolution according to embodiments of the present disclosure, there may be occurred a deviation in emission luminance between subpixels.

Accordingly, the display device 100 according to embodiments of the present disclosure may perform data compensation processing to reduce or eliminate luminance deviation due to deviation in light extraction efficiency between subpixels.

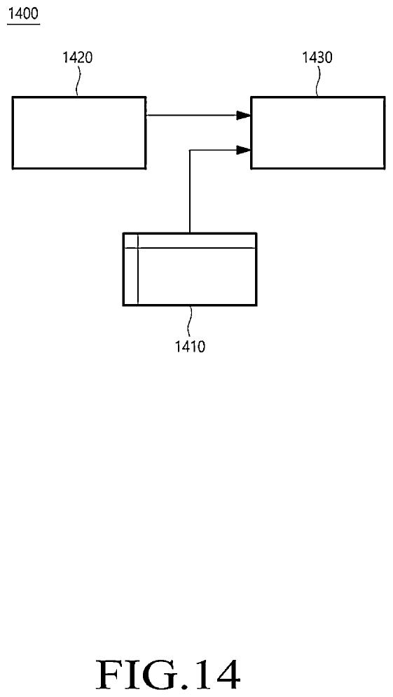

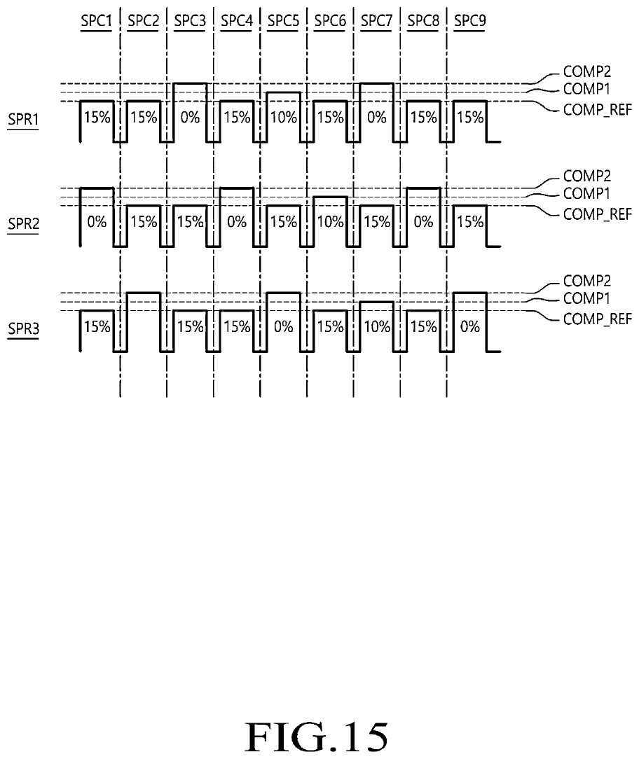

Hereinafter, it will be described a compensation function capable of reducing or eliminating the difference in emission luminance between subpixels caused by a light extraction structure for high-resolution with reference to FIGS. 14 and 15.

FIG. 14 illustrates a data compensation circuit 1400 considering the light extraction structure of a display device 100 according to embodiments of the present disclosure.

Referring to FIG. 14, the data compensation circuit 1400 considering the light extraction structure of the display device 100 according to embodiments of the present disclosure may include a lookup table 1410 including correction control information for each subpixel considering the light extraction structure, a data input unit 1420 which receives data for each subpixel, and a data correction unit 1430 which generates correction data for each subpixel by correcting the data for each subpixel based on correction control information for each subpixel.

For example, the correction control information for each subpixel may include at least one of the number of mirrors for each subpixel, light extraction efficiency for each subpixel, and a data compensation value for each subpixel. The number of mirrors for each subpixel may correspond to or be proportional to the number of inclined surfaces of the common electrode around the light emitting device of the corresponding subpixel. The light extraction efficiency for each subpixel may be proportional to the number of mirrors for each subpixel. The data compensation value for each subpixel may be inversely proportional to the number of mirrors for each subpixel or the light extraction efficiency for each subpixel.

The number of mirrors for each subpixel and the light extraction efficiency for each subpixel may correspond to or be similar to each other. For example, the number of mirrors for each subpixel and the light extraction efficiency for each subpixel may be proportional. The smaller the number of mirrors for each subpixel, the lower the light extraction efficiency for each subpixel, and the greater the number of mirrors for each subpixel, the higher the light extraction efficiency for each subpixel.

The data compensation value for each subpixel may be a value corresponding to the number of mirrors for each subpixel or the light extraction efficiency value for each subpixel. For example, as the number of mirrors decreases, the data compensation value of the corresponding subpixel may increase. The larger the number of mirrors, the smaller the data compensation value of the corresponding subpixel may be. As another example, the lower the light extraction efficiency value, the larger the data compensation value of the corresponding subpixel may be. The higher the light extraction efficiency value, the smaller the data compensation value of the corresponding subpixel may be.

As an example, the data compensation circuit 1400 may be included in the controller 140. As another example, the data compensation circuit 1400 may be included in the data driving circuit 120. As another example, the data compensation circuit 1400 may be provided outside the controller 140 and the data driving circuit 120.

In the case of using the above-described data compensation circuit 1400, even if there is a difference in light extraction efficiency between subpixels due to the light extraction structure for high-resolution according to the embodiments of the present disclosure, the light emission states of subpixels with different light extraction efficiencies may all become the same. Accordingly, there may be prevented the image spotting due to luminance deviation.

Hereinafter, it will be described data compensation of the data compensation circuit 1400 in more detail.

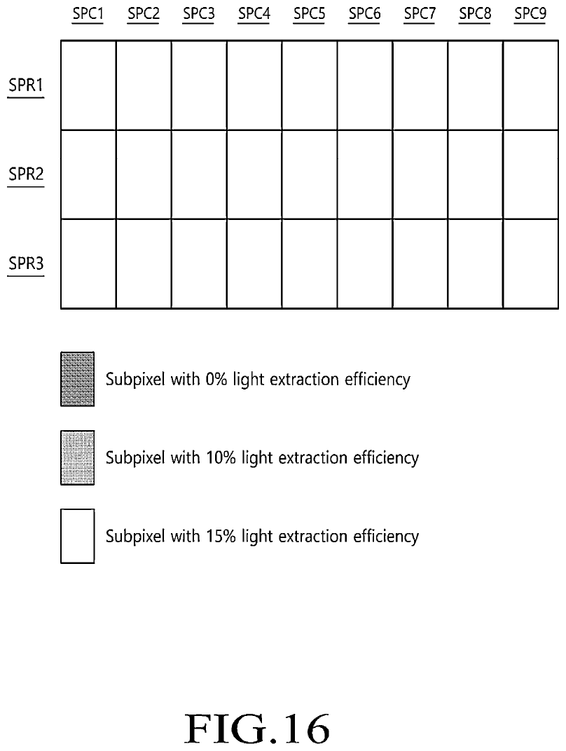

FIG. 15 illustrates data compensation values for each subpixel considering a light extraction structure of the display panel 110 according to embodiments of the present disclosure. FIG. 16 illustrates the light emission state of each subpixel after data compensation considering a light extraction structure of the display panel 110 according to embodiments of the present disclosure.

The data compensation value for each subpixel may be a value considering the light extraction structure. That is, the data compensation value for each subpixel may be a value corresponding to the light extraction efficiency value for each subpixel.

The lower the light extraction efficiency value, the larger the data compensation value of the corresponding subpixel may be. The higher the light extraction efficiency value, the smaller the data compensation value of the corresponding subpixel may be.

A low light extraction efficiency value means that the amount of light emitted to the outside of the display panel 110 is small, resulting in low luminance. Therefore, for the subpixels with low light extraction efficiency values, data compensation processing may be required to supply data capable of further increasing light emission luminance.

A high light extraction efficiency value means that the amount of light emitted to the outside of the display panel 110 is large, resulting in high luminance. Therefore, for a subpixel with a high light extraction efficiency value, data compensation processing may be required to supply data that does not increase the luminance of light or can only slightly increase the luminance.

The data compensation value for each subpixel is a value added to the original data.

As the data compensation value increases, the luminance of the corresponding subpixel may become brighter compared to before data compensation processing.

As the data compensation value is smaller, the luminance of the corresponding subpixel may become slightly brighter than before data compensation processing.

If the data compensation value is zero, the data supplied to the corresponding subpixel has not been compensated, so the luminance of the subpixel does not change.

For example, in the case that the light extraction efficiency value is 15%, the data compensation value of the corresponding subpixels may be a reference compensation value COMP_REF. If the light extraction efficiency value is 10%, the data compensation value of the corresponding subpixels may be a first compensation value COMP1. If the light extraction efficiency value is 0%, the data compensation value of the corresponding subpixels may be a second compensation value COMP2.

For example, the second compensation value COMP2 may be greater than the first compensation value COMP1, and the first compensation value COMP) may be greater than the reference compensation value COMP_REF. For example, the reference compensation value COMP_REF may be zero.

Since the number of mirrors is determined for each subpixel, the light extraction efficiency value for each subpixel and the data compensation value for each subpixel may be predetermined. Accordingly, at least one of the number of mirrors for each subpixel, the light extraction efficiency value for each subpixel, and the data compensation value for each subpixel may be previously stored in the lookup table 1410.

The data correction unit 1430 of the data compensation circuit 1400 considering the light extraction structure may correct the original data for each subpixel and generate correction data for each subpixel by using at least one of the number of mirrors for each subpixel, the light extraction efficiency value for each subpixel, and the data compensation value for each subpixel.

The data driving circuit 120 may convert correction data for each subpixel into a data voltage, which is an analog voltage, and supply it to the corresponding subpixel.

Each of the N first subpixels (e.g., SP11, SP12) included in each second subpixel group 2-SPG may be supplied with a first data voltage for emitting light of the first luminance.

A second data voltage for emitting light of second luminance may be supplied to each of the K second subpixels (e.g., SP13) included in each first subpixel group 1-SPG.

Each of the M third subpixels (e.g., SP14, SP15, SP16) included in each third subpixel group 3-SPG may be supplied with a third data voltage for emitting light of the third luminance.

If the first luminance, second luminance, and third luminance are all the same as shown in FIG. 15, the second data voltage may be different from the first data voltage and the third data voltage. For example, if the first luminance, second luminance, and third luminance are the same, the second data voltage may be higher than the first data voltage and the third data voltage.

Since the number of mirrors in the K second subpixels (e.g., SP13) included in each first subpixel group 1-SPG is 0, the light extraction efficiency value may be the lowest. Accordingly, if data compensation processing is not performed on the K second subpixels (e.g., SP13) included in each first subpixel group 1-SPG, the emission luminance may also be the lowest.

Accordingly, the data compensation value for the K second subpixels (e.g., SP13) included in each first subpixel group 1-SPG may be the highest data compensation value (e.g., the second compensation value COMP2). Accordingly, the second data voltage supplied to the K second subpixels (e.g., SP13) included in each first subpixel group 1-SPG may be the highest.

The case of N=2, K=1, M=3 will be explained as an example as follows.

Among the two first subpixels SP11 and SP12 included in each second subpixel group 2-SPG, the first subpixel SP11 located on the left may be supplied with a first data voltage for emitting light of the first luminance.

Among the two first subpixels SP11 and SP12 included in each second subpixel group 2-SPG, the first subpixel SP12 located on the right may be supplied with a second data voltage for emitting light of the second luminance.

One second subpixel SP13 included in each first subpixel group 1-SPG may be supplied with a third data voltage for emitting light of third luminance.

Among the three third subpixels SP14, SP15 and SP16 included in each third subpixel group 3-SPG, the third subpixel SP14 located on the left may be supplied with a fourth data voltage for emitting light of the fourth luminance.

Among the three third subpixels SP14, SP15 and SP16 included in each third subpixel group 3-SPG, the third subpixel SP15 located in the middle may be supplied with a fifth data voltage for emitting light of the fifth luminance.

Among the three third subpixels SP14, SP15 and SP16 included in each third subpixel group 3-SPG, the third subpixel SP16 located on the right may be supplied with a sixth data voltage for emitting light of the sixth luminance.

If the first to sixth luminances are all the same as shown in FIG. 15, at least one of the first to sixth data voltages may be different from the others. More specifically, if the first to sixth luminances are all the same as shown in FIG. 15, the third data voltage may be higher than the first data voltage, the second data voltage, the fourth data voltage, the fifth data voltage, and the sixth data voltage, and the fifth data voltage may be higher than the first data voltage, the second data voltage, the fourth data voltage, and the sixth data voltage.

Referring to FIG. 16, after data compensation considering the light extraction structure according to embodiments of the present disclosure, the emission states of subpixels with different light extraction efficiencies depending on differences in the light extraction structure may all become the same. Accordingly, it is possible to prevent the image spotting due to luminance deviation.

The display device 100 according to the embodiments of the present disclosure described above may include a substrate 111, a first protective layer 610 on the substrate 111, a first insulating layer 620A located on the first protective layer 610, a second insulating layer 620B located on the first protective layer 610 and laterally spaced apart from the first insulating layer 620A, the first light emitting devices ED11 and ED12 located on the first insulating layer 620A and included in the first subpixels SP11 and SP12, the second light emitting device ED13 located on the first protective layer 610, disposed in a side direction of the first insulating layer 620A and the second insulating layer 620B, and included in the second subpixel SP13, and the third light emitting devices ED14, ED15 and ED16) located on the second insulating layer 620B and included in the third subpixels SP14, SP15 and SP16.

The second light emitting device ED13 may be located closer to the substrate 111 than the first light emitting device ED11 and ED12, and the third light emitting devices ED14, ED15, and ED16.

If the emission luminance of the first subpixels SP11 and SP12, the emission luminance of the second subpixel SP13, and the emission luminance of the third subpixels SP14, SP15, and SP16 are the same, the data voltage supplied to the second subpixel SP13 may be higher than the data voltage supplied to each of the first subpixels SP11 and SP12, and the third subpixels SP14, SP15, and SP16.

The display device 100 according to embodiments of the present disclosure may further include the first pixel electrodes PE11 and PE12 located on the first insulating layer 620A, a second pixel electrode PE13 located on the first protective layer 610 and disposed between one side of the first insulating layer 620A and the other side of the second insulating layer 620B, the third pixel electrodes PE14, PE15 and PE16 located on the second insulating layer 620B, an intermediate layer EL on the first pixel electrodes PE11 and PE12, the second pixel electrode PE13, and the third pixel electrode PE14, PE15 and PE16, and a common electrode CE on the intermediate layer EL.

The first pixel electrodes PE11 and PE12, the intermediate layer EL, and the common electrode CE may constitute the first light emitting devices ED11 and ED12. The second pixel electrode PE13, the intermediate layer EL, and the common electrode CE may constitute the second light emitting device ED13. The third pixel electrodes E14, PE15 and PE16, the intermediate layer EL, and the common electrode CE may constitute third light emitting devices ED14, ED15 and ED16.

The second pixel electrode PE13 may be located closer to the substrate 111 than the first pixel electrodes PE11 and PE12, and the third pixel electrodes PE14, PE15, and PE16.

The common electrode CE may include a reflective electrode material.

The first insulating layer 620A and the second insulating layer 620B may include the same insulating material, and may be separated from each other in the form of an island.

Embodiments of the present disclosure described above are briefly described as follows.

A display device according to embodiments of the present disclosure may include a substrate, a first protective layer located on the substrate, a first insulating layer located on the first protective layer, a second insulating layer located on the first protective layer and disposed on one side of the first insulating layer, N first pixel electrodes located on the first insulating layer, K second pixel electrodes located on the first protective layer and disposed between one side of the first insulating layer and the other side of the second insulating layer, and M third pixel electrodes located on the second insulating layer. The N may be a natural number greater than or equal to 2, K may be a natural number greater than or equal to 1, and M may be a natural number greater than or equal to 2.

A display device according to embodiments of the present disclosure may further include an intermediate layer located on the N first pixel electrodes, the K second pixel electrodes, and the M third pixel electrodes, and a common electrode located on the intermediate layer.

In the display device according to embodiments of the present disclosure, the K second pixel electrodes may be located closer to the substrate than the N first pixel electrodes and the M third pixel electrodes.

In the display device according to embodiments of the present disclosure, the common electrode may include a reflective electrode material.

In the display device according to embodiments of the present disclosure, the common electrode may have an inclined surface on a side of the first insulating layer, and may have an inclined surface on a side of the second insulating layer. For example, the common electrode may have inclined surfaces on four sides of the first insulating layer and may have inclined surfaces on four sides of the second insulating layer. For example, the common electrode may have an inclined surface on each of one side of the first insulating layer and the other side of the second insulating layer.

In the display device according to embodiments of the present disclosure, the common electrode may include a first common electrode part located on the first insulating layer, a second common electrode part disposed between one side of the first insulating layer and the other side of the second insulating layer and located on the first protective layer, a third common electrode part located on the second insulating layer, a first connection part connecting the first common electrode part and the second common electrode part, and a second connection part connecting the second common electrode part and the third common electrode part.

The second common electrode part may be located closer to the substrate than the first common electrode part and the third common electrode part.

The first connection part and the second connection part may be formed to be inclined. That is, each of the first connection part and the second connection part may have an inclined surface.

According to the display device according to the embodiments of the present disclosure, the second common electrode part may be located farther from the substrate than the K second pixel electrodes, and may be located closer to the substrate than the N first pixel electrodes and the M third pixel electrodes.

According to the display device according to the embodiments of the present disclosure, the first insulating layer and the second insulating layer may include the same insulating material, and may be separated from each other in an island shape.

According to the display device according to the embodiments of the present disclosure, a first data voltage for emitting light of a first luminance may be supplied to each of the N first subpixels including the N first pixel electrodes, a second data voltage for emitting light of a second luminance may be supplied to each of the K second subpixels including the K second pixel electrodes, and a third data voltage for emitting light of a third luminance may be supplied to each of the M third subpixels including the M third pixel electrodes. If the first luminance, the second luminance, and the third luminance are the same, the second data voltage may be different from the first data voltage and the third data voltage.

According to the display device according to the embodiments of the present disclosure, if the first luminance, the second luminance, and the third luminance are the same, the second data voltage may be higher than the first data voltage and the third data voltage.

The display device according to the embodiments of the present disclosure further include a third insulating layer located on the first protective layer, a fourth insulating layer located on the first protective layer, N fourth pixel electrodes located on the third insulating layer, K fifth pixel electrodes located on the first protective layer and disposed between one side of the third insulating layer and the other side of the fourth insulating layer, and M sixth pixel electrodes located on the fourth insulating layer.

According to the display device according to the embodiments of the present disclosure, the third insulating layer and the fourth insulating layer may include the same insulating material, and may be separated from each other in an island shape.

According to the display device according to the embodiments of the present disclosure, the first insulating layer and the second insulating layer may be disposed in a first subpixel row, and the third insulating layer and the fourth insulating layer may be disposed in a second subpixel row different from the first subpixel row.

According to the display device according to the embodiments of the present disclosure, N first subpixels including the N first pixel electrodes, K second subpixels including the K second pixel electrodes, and M third subpixels including the M third pixel electrodes may be arranged in a first subpixel row, and N fourth subpixels including the N fourth pixel electrodes, K fifth subpixels including the K fifth pixel electrodes, and M sixth subpixels including the M sixth pixel electrodes may be arranged in a second subpixel row.

According to the display device according to the embodiments of the present disclosure, the N first subpixels may be respectively arranged in first to Nth subpixel columns. The N fourth subpixels may be respectively arranged in the second to (N+1)th subpixel columns shifted by one subpixel width.

According to the display device according to the embodiments of the present disclosure, if N first subpixels including the N first pixel electrodes, K second subpixels including the K second pixel electrodes, and M third subpixels including the M third pixel electrodes are arranged in a first subpixel row, the N may be 2, the K may be 1, and the M may be 3. In this case, the first subpixel row may include two first subpixels, one second subpixel, and three third subpixels, the two first subpixels may include two first pixel electrodes on the first insulating layer, respectively, the one second subpixel may include one second pixel electrode on the first protective layer, and the three third subpixels may include three third pixel electrodes on the second insulating layer, respectively.

According to the display device according to embodiments of the present disclosure, if M is greater than N, the second insulating layer may be disposed longer than the first insulating layer.

According to the display device according to embodiments of the present disclosure, the common electrode may include three first inclined surfaces located on three of four sides of a first subpixel located on the left of the two first subpixels, three second inclined surfaces located on three of the four sides of the first subpixel located on the right of the two first subpixels, three third inclined surfaces located on three of the four sides of the third subpixel located on the left among the three third subpixels, two fourth inclined surfaces located on two of four sides of a third subpixel located in the middle of the three third subpixels, and three fifth inclined surfaces located on three of the four sides of the third subpixel located on the right among the three third subpixels.

According to the display device according to embodiments of the present disclosure, the three first inclined surfaces and the three second inclined surfaces may be formed on a side surface of the first insulating layer, and the three third inclined surfaces, the two fourth inclined surfaces, and the three fifth inclined surfaces may be formed on a side surface of the second insulating layer.

According to the display device according to embodiments of the present disclosure, light emitted from the first subpixel located on the left may be reflected from three first inclined surfaces, and light emitted from the first subpixel located on the right is reflected from three second inclined surfaces, light emitted from the third subpixel located on the left may be reflected from the three third inclined surfaces, light emitted from the third subpixel located in the middle may be reflected from the two fourth inclined surfaces, and light emitted from the third subpixel located on the right may be reflected from the three fifth inclined surfaces. The first to fifth inclined surfaces may correspond to mirrors.

According to the display device according to embodiments of the present disclosure, the first subpixel located on the left may be supplied with a first data voltage for emitting light of a first luminance, the first subpixel located on the right may be supplied with a second data voltage for emitting light of a second luminance, the one second subpixel may be supplied with a third data voltage for emitting light of a third luminance, the third subpixel located on the left may be supplied with a fourth data voltage for emitting light of a fourth luminance, the third subpixel located in the middle may be supplied with a fifth data voltage for emitting light of a fifth luminance, and the third subpixel located on the right may be supplied with a sixth data voltage for emitting light of a sixth luminance. If the first to sixth luminances are all the same, the third data voltage may be higher than the first data voltage, the second data voltage, the fourth data voltage, and the fifth data voltage, and the fifth data voltage may be higher than the first data voltage, the second data voltage, and the fourth data voltage.

A display device according to embodiments of the present disclosure may include a substrate, a first pixel electrode, a second pixel electrode, and a third pixel electrode on the substrate, an intermediate layer on the first pixel electrode, the second pixel electrode, and the third pixel electrode, and a common electrode on the intermediate layer. The first pixel electrode and the third pixel electrode may be located higher from the substrate than the second pixel electrode.

According to the display device according to embodiments of the present disclosure, the common electrode may include an inclined surface extending from an upper portion of the first pixel electrode, passing through one side of the first pixel electrode, and extending to an upper portion of the second pixel electrode, and an inclined surface extending from an upper portion the third pixel electrode, passing through the other side of the third pixel electrode, and extending to an upper portion of the second pixel electrode.

The display device according to embodiments of the present disclosure may further include an insulating layer which is not disposed below the second pixel electrode, but is disposed below the first pixel electrode and the third pixel electrode.

A display device according to embodiments of the present disclosure may include a substrate, a first protective layer on the substrate, a first insulating layer located on the first protective layer, a second insulating layer located on the first protective layer and laterally spaced apart from the first insulating layer, a first light emitting device located on the first insulating layer and included in a first subpixel, a second light emitting device located on the first protective layer, disposed in a lateral direction of the first insulating layer and the second insulating layer, and included in a second subpixel, and a third light emitting device located on the second insulating layer and included in the third subpixel.

According to the display device according to embodiments of the present disclosure, the second light emitting device may be located closer to the substrate than the first light emitting device and the third light emitting device.

According to the display device according to embodiments of the present disclosure, if an emission luminance of the first subpixel, an emission luminance of the second subpixel, and an emission luminance of the third subpixel are the same, a data voltage supplied to the second subpixel may be higher than a data voltage supplied to each of the first subpixel and the third subpixel.

The display device according to embodiments of the present disclosure may further include a first pixel electrode located on the first insulating layer and included in the first light emitting device, a second pixel electrode located on the first protective layer, disposed between one side of the first insulating layer and the other side of the second insulating layer, and included in the second light emitting device, and a third pixel electrode located on the second insulating layer and included in the third light emitting device.

The display device according to embodiments of the present disclosure may further include an intermediate layer on the first pixel electrode, the second pixel electrode, and the third pixel electrode, and a common electrode on the intermediate layer.

According to the display device according to embodiments of the present disclosure, the second pixel electrode may be located closer to the substrate than the first pixel electrode and the third pixel electrode,

According to the display device according to embodiments of the present disclosure, the common electrode may include an inclined surface extending from an upper portion of the first pixel electrode, passing through one side of the first pixel electrode, and extending to an upper portion of the second pixel electrode, and an inclined surface extending from an upper portion of the third pixel electrode, passing through the other side of the third pixel electrode, and extending to an upper portion of the second pixel electrode.

According to the display device according to embodiments of the present disclosure, the second pixel electrode may be located closer to the substrate than the first pixel electrode and the third pixel electrode.

According to the display device according to embodiments of the present disclosure, the common electrode may include a reflective electrode material.

According to the display device according to the embodiments of the present disclosure, the common electrode may have an inclined surface on one side of the first insulating layer and the other side of the second insulating layer, respectively.

According to the display device according to embodiments of the present disclosure, the first insulating layer and the second insulating layer may include the same insulating material, and may be separated from each other in an island shape.

According to embodiments of the present disclosure as described above, it is possible to provide a display device having a light extraction structure which allows a greater amount of light among the light generated by the light emitting devices in the display panel to be emitted toward a viewing surface.

According to embodiments of the present disclosure, it is possible to provide a display device having a light extraction structure suitable for a high-resolution display panel.

According to embodiments of the present disclosure, it is possible to provide a display device with a compensation function capable of reducing luminance deviation for each subpixel according to a light extraction structure suitable for high-resolution display panels.

According to embodiments of the present disclosure, it is possible to increase the light extraction efficiency for light generated from light emitting devices in the display panel. Accordingly, it is possible to reduce the power consumption of the display device by increasing light extraction efficiency.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display device, comprising:
a substrate;
a first protective layer located on the substrate;
a first insulating layer located on the first protective layer;
a second insulating layer located on the first protective layer and disposed on one side of the first insulating layer;
N first pixel electrodes located on the first insulating layer;
K second pixel electrodes located on the first protective layer and disposed between one side of the first insulating layer and one side of the second insulating layer which is adjacent to the one side of the first insulating layer; and
M third pixel electrodes located on the second insulating layer,
wherein N is a natural number greater than or equal to 2, K is a natural number greater than or equal to 1, and M is a natural number greater than or equal to 2.

2. The display device of claim 1, wherein the K second pixel electrodes are located closer to the substrate than the N first pixel electrodes and the M third pixel electrodes.

3. The display device of claim 1, further comprising:
an intermediate layer located on the N first pixel electrodes, the K second pixel electrodes, and the M third pixel electrodes; and
a common electrode located on the intermediate layer,
wherein the common electrode has an inclined surface on a side of the first insulating layer, and an inclined surface on a side of the second insulating layer.

4. The display device of claim 3, further comprising:
a bank disposed between any one of the N first pixel electrodes, the K second pixel electrodes and the M third pixel electrodes and the intermediate layer, wherein the bank covers the ends of the any one of the N first pixel electrodes, the K second pixel electrodes and the M third pixel electrodes.

5. The display device of claim 3, wherein
when a bank does not exist between any one of the N first pixel electrodes, the K second pixel electrodes and the M third pixel electrodes and the intermediate layer, the side surfaces of both ends of the any one of the N first pixel electrodes, the K second pixel electrodes and the M third pixel electrodes have a regular taper shape.

6. The display device of claim 1, wherein the first insulating layer and the second insulating layer are layers of the same insulating material, and are separated from each other in an island shape.

7. The display device of claim 1, wherein, if M is greater than N, the second insulating layer is disposed longer than the first insulating layer.

8. The display device of claim 1, further comprising:
an intermediate layer located on the N first pixel electrodes, the K second pixel electrodes, and the M third pixel electrodes; and
a common electrode located on the intermediate layer,
wherein the common electrode comprises:
a first common electrode part located on the first insulating layer;
a second common electrode part disposed between one side of the first insulating layer and one side of the second insulating layer which is adjacent to the one side of the first insulating layer, and located on the first protective layer;
a third common electrode part located on the second insulating layer;
a first connection part connecting the first common electrode part and the second common electrode part; and
a second connection part connecting the second common electrode part and the third common electrode part,
wherein each of the first connection part and the second connection part has an inclined surface.

9. The display device of claim 8, wherein the second common electrode part is located closer to the substrate than the N first pixel electrodes and the M third pixel electrodes.

10. The display device of claim 1, wherein a first data voltage for emitting light of a first luminance is supplied to each of the N first subpixels including the N first pixel electrodes,
wherein a second data voltage for emitting light of a second luminance is supplied to each of the K second subpixels including the K second pixel electrodes,
wherein a third data voltage for emitting light of a third luminance is supplied to each of the M third subpixels including the M third pixel electrodes,
wherein, if the first luminance, the second luminance, and the third luminance are the same, the second data voltage is higher than the first data voltage and the third data voltage.

11. The display device of claim 1, further comprising:
a third insulating layer located on the first protective layer;
a fourth insulating layer located on the first protective layer;
a fifth insulating layer located on the first protective layer;
N fourth pixel electrodes located on the third insulating layer;
K fifth pixel electrodes located on the first protective layer and disposed between one side of the fourth insulating layer and one side of the fifth insulating layer which is adjacent to the one side of the fourth insulating layer; and
M sixth pixel electrodes located on the fifth insulating layer.

12. The display device of claim 11, wherein the fourth insulating layer and the fifth insulating layer are layers of the same insulating material, and are separated from each other in an island shape,
wherein the first insulating layer, the second insulating layer, and the third insulating layer are disposed in a first subpixel row,
wherein the fourth insulating layer and the fifth insulating layer are disposed in a second subpixel row different from the first subpixel row.

13. The display device of claim 11, wherein N first subpixels including the N first pixel electrodes, K second subpixels including the K second pixel electrodes, and M third subpixels including the M third pixel electrodes are arranged in a first subpixel row,
wherein N fourth subpixels including the N fourth pixel electrodes, K fifth subpixels including the K fifth pixel electrodes, and M sixth subpixels including the M sixth pixel electrodes are arranged in a second subpixel row,
wherein the N first subpixels are respectively arranged in first to Nth subpixel columns,
wherein the N fourth subpixels are respectively arranged in the second to (N+1)th subpixel columns shifted by one subpixel width.

14. The display device of claim 1, wherein N first subpixels including the N first pixel electrodes, K second subpixels including the K second pixel electrodes, and M third subpixels including the M third pixel electrodes are arranged in a first subpixel row,
wherein the N is 2, the K is 1, and the M is 3,
wherein the first subpixel row includes two first subpixels, one second subpixel, and three third subpixels,
wherein the two first subpixels includes two first pixel electrodes on the first insulating layer, respectively, the one second subpixel includes one second pixel electrode on the first protective layer, and the three third subpixels include three third pixel electrodes on the second insulating layer, respectively.

15. The display device of claim 14, further comprising:
an intermediate layer located on the N first pixel electrodes, the K second pixel electrodes, and the M third pixel electrodes; and
a common electrode on the intermediate layer,
wherein the common electrode comprises:
three first inclined surfaces located on three of four sides of a first subpixel located on the left of the two first subpixels;
three second inclined surfaces located on three of the four sides of the first subpixel located on the right of the two first subpixels;
three third inclined surfaces located on three of the four sides of the third subpixel located on the left among the three third subpixels;
two fourth inclined surfaces located on two of four sides of a third subpixel located in the middle of the three third subpixels; and
three fifth inclined surfaces located on three of the four sides of the third subpixel located on the right among the three third subpixels.

16. The display device of claim 15, wherein the three first inclined surfaces and the three second inclined surfaces are formed on a side surface of the first insulating layer,
wherein the three third inclined surfaces, the two fourth inclined surfaces, and the three fifth inclined surfaces are formed on a side surface of the second insulating layer.

17. The display device of claim 15, wherein light emitted from the first subpixel located on the left is reflected from the three first inclined surfaces, and light emitted from the first subpixel located on the right is reflected from the three second inclined surfaces,
wherein light emitted from the third subpixel located on the left is reflected from the three third inclined surfaces, light emitted from the third subpixel located in the middle is reflected from the two fourth inclined surfaces, and light emitted from the third subpixel located on the right is reflected from the three fifth inclined surfaces.

18. The display device of claim 15, wherein the first subpixel located on the left is supplied with a first data voltage for emitting light of a first luminance, and the first subpixel located on the right is supplied with a second data voltage for emitting light of a second luminance,
wherein the one second subpixel is supplied with a third data voltage for emitting light of a third luminance,
wherein the third subpixel located on the left is supplied with a fourth data voltage for emitting light of a fourth luminance, and the third subpixel located in the middle is supplied with a fifth data voltage for emitting light of a fifth luminance, and the third subpixel located on the right is supplied with a sixth data voltage for emitting light of a sixth luminance,
wherein, if the first to sixth luminances are all the same,
the third data voltage is higher than the first data voltage, the second data voltage, the fourth data voltage, the fifth data voltage, and the sixth data voltage, and
the fifth data voltage is higher than the first data voltage, the second data voltage, the fourth data voltage, and the sixth data voltage.

19. A display device, comprising;
a substrate;
a first pixel electrode, a second pixel electrode, and a third pixel electrode on the substrate;
an intermediate layer on the first pixel electrode, the second pixel electrode, and the third pixel electrode; and
a common electrode on the intermediate layer,
wherein the first pixel electrode and the third pixel electrode are located higher from the substrate than the second pixel electrode,
wherein the common electrode comprises:
an inclined surface extending from an upper portion of the first pixel electrode, passing through one side of the first pixel electrode, and extending to an upper portion of the second pixel electrode; and
an inclined surface extending from an upper portion the third pixel electrode, passing through one side of the third pixel electrode which is adjacent to one side of the first pixel electrode, and extending to an upper portion of the second pixel electrode.

20. The display device of claim 19, further comprising an insulating layer which is not disposed below the second pixel electrode, but is disposed below the first pixel electrode and the third pixel electrode.

21. A display device, comprising;
a substrate;
a first protective layer on the substrate;
a first insulating layer located on the first protective layer;
a second insulating layer located on the first protective layer and laterally spaced apart from the first insulating layer;
a first light emitting device located on the first insulating layer and included in a first subpixel;
a second light emitting device located on the first protective layer, disposed in a lateral direction of the first insulating layer and the second insulating layer, and included in a second subpixel; and
a third light emitting device located on the second insulating layer and included in the third subpixel,
wherein the second light emitting device is located closer to the substrate than the first light emitting device and the third light emitting device,
wherein, if an emission luminance of the first subpixel, an emission luminance of the second subpixel, and an emission luminance of the third subpixel are the same, a data voltage supplied to the second subpixel is higher than a data voltage supplied to each of the first subpixel and the third subpixel.

22. The display device of claim 21, further comprising:
a first pixel electrode located on the first insulating layer and included in the first light emitting device;
a second pixel electrode located on the first protective layer, disposed between one side of the first insulating layer and one side of the second insulating layer which is adjacent to one side of the first insulating layer, and included in the second light emitting device;
a third pixel electrode located on the second insulating layer and included in the third light emitting device;
an intermediate layer on the first pixel electrode, the second pixel electrode, and the third pixel electrode; and
a common electrode on the intermediate layer,
wherein the second pixel electrode is located closer to the substrate than the first pixel electrode and the third pixel electrode,
wherein the common electrode comprises:
an inclined surface extending from an upper portion of the first pixel electrode, passing through one side of the first pixel electrode, and extending to an upper portion of the second pixel electrode; and
an inclined surface extending from an upper portion of the third pixel electrode, passing through one side of the third pixel electrode which is adjacent to the one side of the first pixel electrode, and extending to an upper portion of the second pixel electrode.
